(19) United States
(12) Patent Application Publication
(10) Pub. No.: US 2025/0364787 A1
(43) Pub. Date: Nov. 27, 2025

(54) VERTICAL CAVITY LIGHT-EMITTING ELEMENT AND MANUFACTURING METHOD THEREOF

(71) Applicant: STANLEY ELECTRIC CO., LTD., Meguro-ku, Tokyo (JP)

(72) Inventors: Yuhzoh TSUDA, Tokyo (JP); Hirotaka ONO, Tokyo (JP); Masaru KURAMOTO, Tokyo (JP)

(73) Assignee: STANLEY ELECTRIC CO., LTD., Meguro-ku, Tokyo (JP)

(21) Appl. No.: 18/873,750

(22) PCT Filed: Jun. 7, 2023
(86) PCT No.: PCT/JP2023/021148

§ 371 Date: Dec. 11, 2024

(30) Foreign Application Priority Data
Jun. 17, 2022 (JP) 2022-098368

(51) Int. Cl. H01S 5/183; H01S 5/02; H01S 5/343

(52) U.S. Cl. CPC H01S 5/18377; H01S 5/0206; H01S 5/34333; H01S 5/18369; H01S 2304/04

(57) ABSTRACT

A vertical cavity light-emitting element includes a p-type AlGaN layer that contains Mg and includes three or more stacked AlGaN layers with different Al compositions. When the AlGaN layer is divided into, from an active layer side, a first region having a layer thickness of 1/10, a second region having a layer thickness of ⅖, and a third region having a layer thickness of ½ in this order, a size relationship among Al compositions indicated by an Al composition curve is the first region<the third region<the second region. The Mg concentration indicated by an Mg concentration curve is less than 3x10¹⁹ atoms/cm³ throughout an entire thickness of the AlGaN layer. A size relationship among Mg concentrations is the first region<the second region<the third region. The Mg concentration in at least part of the second region is 3×10¹⁸ atoms/cm³ or more.

### TECHNICAL FIELD

The present invention relates to a vertical cavity light-emitting element using a semiconductor multilayer film reflecting mirror, in particular a vertical cavity semiconductor light-emitting element such as a vertical cavity surface emitting laser (VCSEL). The present invention also relates to a manufacturing method of the vertical cavity light-emitting element.

### BACKGROUND ART

It is known that a vertical cavity light-emitting element includes distributed Bragg reflectors (DBR) above and below an active layer. In semiconductor light-emitting elements, it is known that an electron blocking layer with a band gap energy higher than that of the active layer is used to suppress the overflow of the electron carriers.

For example, in Patent Document 1, a vertical cavity light-emitting element constituted of a GaN-based semiconductor is disclosed, which includes an AlGaN layer as an electron blocking layer between an active layer and a p-type semiconductor mesa structure. In addition, in Patent Document 1, it is disclosed that the band gap energy is increased by increasing Al composition of the electron blocking layer.
Patent Document 1: Japanese Patent No. 6966843 B

### DISCLOSURE OF THE INVENTION

### Problems to be Solved by the Invention

For example, in the vertical cavity light-emitting element described above, when a p-type dopant concentration in a p-type AlGaN layer is increased, concentration of the hole carriers increases, resulting in an effect of higher carrier injection efficiency. However, if the concentration of p-type dopant is increased too much, there is a problem that an element life is likely to decrease due to diffusion of the p-type dopant into the active layer and spread of defects in the active layer caused by the high concentration of the p-type dopant.

The present invention has been made in view of the above-described problem and an objective of which is to provide a long-life, highly efficient vertical cavity light-emitting element and a manufacturing method thereof while allowing a high carrier injection efficiency and suppressing a decrease in an element life.

### Solutions to the Problems

A vertical cavity light-emitting element according to the present invention includes a substrate, a first multilayer film reflecting mirror, an n-type nitride semiconductor layer, an active layer, a p-type AlGaN layer, a p-type nitride semiconductor layer, and a second multilayer film reflecting mirror. The first multilayer film reflecting mirror as a semiconductor multilayer film in which two semiconductor layers with mutually different refractive indices are stacked alternately a plurality of times on the substrate. The n-type nitride semiconductor layer is formed on the first multilayer film reflecting mirror and made of a nitride semiconductor containing an n-type dopant. The active layer is formed on the n-type nitride semiconductor layer. The p-type AlGaN layer is formed on the active layer and containing Mg as a p-type dopant. The p-type AlGaN layer having a configuration in which three or more AlGaN layers with different Al compositions are stacked. The p-type nitride semiconductor layer is formed on the p-type AlGaN layer. The p-type nitride semiconductor layer is a semiconductor layer made of a nitride semiconductor containing a p-type dopant. The second multilayer film reflecting mirror formed on the p-type nitride semiconductor layer and provided in a position opposed to the first multilayer film reflecting mirror. In an Al composition curve indicating a change in Al composition in a layer thickness direction in the p-type AlGaN layer and a Mg concentration curve indicating a change in Mg concentration in the layer thickness direction in the p-type AlGaN layer analyzed by a secondary ion mass spectrometry (SIMS) of the p-type AlGaN layer, when a width range at 50% of the peak value of the Al composition curve is defined as the p-type AlGaN layer, and the p-type AlGaN layer is divided into a first region having a layer thickness of 1/10 of the p-type AlGaN layer, a second region having a layer thickness of ⅖ of the p-type AlGaN layer, and a third region having a layer thickness of ½ of the p-type AlGaN layer in the layer thickness direction from the active layer side in this order, a size relationship among the Al compositions indicated by the Al composition curve in the respective regions is the first region<the third region<the second region, a Mg concentration indicated by the Mg concentration curve is less than 3×10¹⁹ atoms/cm³ throughout an entire layer thickness of the p-type AlGaN layer, and a size relationship among the Mg concentrations in the respective regions is the first region<the second region<the third region, the Mg concentration in at least a partial region of the second region is 3×10¹⁸ atoms/cm³ or more, and, the Mg concentration curve has a peak in the second region.

A vertical cavity light-emitting element according to the present invention includes a substrate, a first multilayer film reflecting mirror, an n-type nitride semiconductor layer, an active layer, a p-type AlGaN layer, a p-type nitride semiconductor layer, and a second multilayer film reflecting mirror. The first multilayer film reflecting mirror is a semiconductor multilayer film in which two semiconductor layers with mutually different refractive indices are stacked alternately a plurality of times on the substrate. The n-type nitride semiconductor layer is formed on the first multilayer film reflecting mirror and made of a nitride semiconductor containing an n-type dopant. The active layer is formed on the n-type nitride semiconductor layer. The p-type AlGaN layer is formed on the active layer and contains Mg as a p-type dopant. The p-type AlGaN layer has a configuration in which three or more AlGaN layers with different Al compositions are stacked. The p-type nitride semiconductor layer is formed on the p-type AlGaN layer. The p-type nitride semiconductor layer being a semiconductor layer made of a nitride semiconductor containing a p-type dopant. The second multilayer film reflecting mirror is formed on the p-type nitride semiconductor layer and provided in a position opposed to the first multilayer film reflecting mirror. In an Al composition curve indicating a change in Al composition in a layer thickness direction in the p-type AlGaN layer and a Mg concentration curve indicating a change in Mg concentration in the layer thickness direction in the p-type AlGaN layer analyzed by a secondary ion mass spectrometry (SIMS) of the p-type AlGaN layer, when a width range at 50% of the peak value of the Al composition curve is defined as the p-type AlGaN layer, and the p-type AlGaN layer is divided into a first region having a layer thickness of 1/10 of the p-type AlGaN layer, a second region having a layer thickness of ⅖ of the p-type AlGaN layer, and a third region having a layer thickness of ½ of the p-type AlGaN layer in the layer thickness direction from the active layer side in this order, a size relationship among the Al compositions indicated by the Al composition curve in the respective regions is the first region<the third region<the second region, a Mg concentration indicated by the Mg concentration curve is less than 3×10¹⁹ atoms/cm³ throughout an entire layer thickness of the p-type AlGaN layer, and a size relationship among the Mg concentrations in the respective regions is the first region<the second region<the third region, a mean value of the Mg concentrations in the second region is 3×10¹⁸ atoms/cm³ or more, and the Mg concentration curve in the second region is configured such that a mean value of absolute values of a slope in a portion of the third region side is smaller than a mean value of absolute values of a slope in a portion of the first region side with respect to a center of the second region in the layer thickness direction, in the second region.

A manufacturing method of a vertical cavity light-emitting element by a metal-organic chemical vapor deposition (MOCVD) according to the present invention includes a step of forming a first multilayer film reflecting mirror by alternately growing two semiconductor layers with mutually different refractive indices on a substrate; an n-type nitride semiconductor layer growth step of growing an n-type nitride semiconductor layer on the first multilayer film reflecting mirror while supplying a material gas of n-type dopant; a step of forming an active layer on the n-type nitride semiconductor layer; a p-type AlGaN layer growth step of growing a p-type AlGaN layer that is an AlGaN layer having a p-type conductivity type on the active layer while supplying a material gas of Mg as a p-type dopant; a p-type nitride semiconductor layer growth step of growing a p-type nitride semiconductor layer on the p-type AlGaN layer; and a step of forming a second multilayer film reflecting mirror opposed to the first multilayer film reflecting mirror on the p-type nitride semiconductor layer. The p-type AlGaN layer growth step includes: a first growth step of growing a first p-type AlGaN layer by supplying a nitrogen source gas and a Ga material gas at a predetermined supply amount, supplying an Al material gas at a first supply amount, and supplying the Mg material gas at a second supply amount while increasing a growth temperature from a first temperature to a second temperature; a second growth step of growing a second p-type AlGaN layer while maintaining the supply amounts of the nitrogen source gas, the Ga material gas, the Al material gas, and the Mg material gas used in the first growth step after the first growth step; and a third growth step of growing a third p-type AlGaN layer while supplying the Al material gas at a third supply amount lower than the first supply amount, and supplying the Mg material gas at a fourth supply amount lower than the second supply amount after the second growth step.

A manufacturing method of a vertical cavity light-emitting element by a metal-organic chemical vapor deposition (MOCVD) according to the present invention includes: a step of forming a first multilayer film reflecting mirror by alternately growing two semiconductor layers with mutually different refractive indices on a substrate; an n-type nitride semiconductor layer growth step of growing an n-type nitride semiconductor layer on the first multilayer film reflecting mirror while supplying a material gas of n-type dopant; a step of forming an active layer on the n-type nitride semiconductor layer; a p-type AlGaN layer growth step of growing a p-type AlGaN layer that is an AlGaN layer having a p-type conductivity type on the active layer while supplying a material gas of Mg as a p-type dopant; a p-type nitride semiconductor layer growth step of growing a p-type nitride semiconductor layer on the p-type AlGaN layer; and a step of forming a second multilayer film reflecting mirror opposed to the first multilayer film reflecting mirror on the p-type nitride semiconductor layer. The p-type AlGaN layer growth step includes: a pre-processing step of supplying a nitrogen source gas at a predetermined supply amount, and supplying the Mg material gas at the first supply amount while increasing a growth temperature from a first temperature to a second temperature; a first growth step of growing a first p-type AlGaN layer by supplying a Ga material gas at a predetermined supply amount, supplying an Al material gas at a second supply amount, and supplying the Mg material gas at a third supply amount while continuing the supply of the nitrogen source gas after the pre-processing step; a second growth step of growing a second p-type AlGaN layer while maintaining the supply amounts of the nitrogen source gas, the Ga material gas, the Al material gas, and the Mg material gas used in the first growth step after the first growth step; and a third growth step of growing a third p-type AlGaN layer while supplying the Al material gas at a fourth supply amount lower than the second supply amount, and supplying the Mg material gas at a fifth supply amount lower than the third supply amount after the second growth step.

### BRIEF DESCRIPTION OF THE DRAWINGS

FIG. 1 is a perspective view illustrating a configuration of a surface emitting laser according to Embodiment 1.

FIG. 2 is a top view illustrating a configuration of the surface emitting laser according to Embodiment 1.

FIG. 3 is a cross-sectional view illustrating a configuration of the surface emitting laser according to Embodiment 1.

FIG. 4 is a diagram showing a SIMS analysis result of a p-type AlGaN layer of the surface emitting laser according to Embodiment 1.

FIG. 5 is a flowchart illustrating an overview of a manufacturing process of the surface emitting laser according to Embodiment 1.

FIG. 6 is a diagram schematically illustrating a growth sequence of the p-type AlGaN layer of the surface emitting laser according to Embodiment 1.

FIG. 7 is a diagram showing a SIMS analysis result of a p-type AlGaN layer of a surface emitting laser according to a comparative example.

FIG. 8 is a diagram showing a SIMS analysis result of a p-type AlGaN layer of a surface emitting laser according to a comparative example.

FIG. 9 is a diagram showing a SIMS analysis result of a p-type AlGaN layer of a surface emitting laser according to Embodiment 2.

FIG. 10 is a diagram showing a SIMS analysis result of a p-type AlGaN layer of a surface emitting laser according to a modification of Embodiment 2.

FIG. 11 is a diagram schematically illustrating a growth sequence of the p-type AlGaN layer of the surface emitting laser according to the modification of Embodiment 2.

FIG. 12 is a diagram showing a SIMS analysis result of a p-type AlGaN layer of a surface emitting laser according to another modification of Embodiment 2.

FIG. 13 is a diagram showing a SIMS analysis result of the p-type AlGaN layer of the surface emitting laser according to another modification of Embodiment 2.

FIG. 14 is a cross-sectional view illustrating a configuration of a surface emitting laser according to Embodiment 3.

FIG. 15 is a diagram showing a SIMS analysis result of a p-type AlGaN layer of the surface emitting laser according to Embodiment 3.

FIG. 16 is a diagram schematically illustrating a growth sequence of the p-type AlGaN layer of the surface emitting laser according to Embodiment 3.

### DESCRIPTION OF PREFERRED EMBODIMENTS

The following describes preferred embodiments of the present invention, but these may be modified and combined as appropriate. In the following description and accompanying drawings, substantially identical or equivalent parts are described using the same reference symbols.

### Embodiment 1

Referring to the attached drawings, a configuration of a vertical cavity surface emitting laser (VCSEL, hereinafter simply referred to as a surface emitting laser) 10 according to Embodiment 1 of the present invention is described. The surface emitting laser 10 of Embodiment 1 is constituted of nitride-based semiconductor layers.

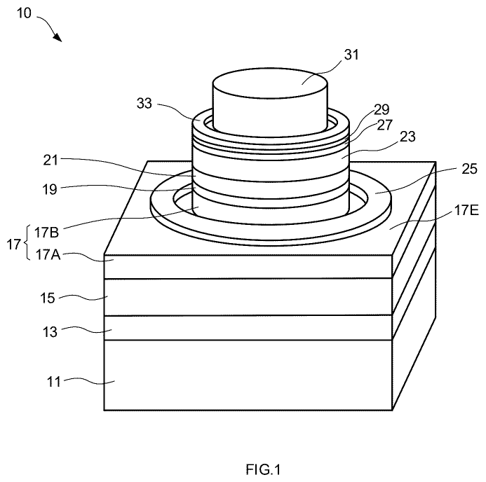

FIG. 1 is a perspective view illustrating an overview of the configuration of the surface emitting laser 10.

A substrate 11 is a substrate for growing nitride semiconductor layers constituting the surface emitting laser 10. For example, the substrate 11 has a rectangular top surface shape. In this embodiment, the substrate 11 is a GaN substrate. A top surface of the substrate 11, that is, a surface on which the nitride semiconductor layers are grown, is preferably a C-plane or a surface that is offset from the C-plane by equal to or less than 1°. In addition to the GaN substrate, a substrate such as a sapphire substrate and an AlN substrate can also be used as the substrate 11.

An underlayer 13 is formed on the substrate 11. The underlayer 13 is an undoped GaN layer. The underlayer 13 functions as a buffer layer to enhance crystallinity of the nitride semiconductor layers grown on the underlayer 13.

A first multilayer film reflecting mirror 15 is formed on the underlayer 13. The first multilayer film reflecting mirror 15 is a semiconductor multilayer film reflecting mirror in which a low refractive index semiconductor film with an AlInN composition and a high refractive index semiconductor film with a GaN composition having a higher refractive index than the low refractive index semiconductor film are alternately laminated. The first multilayer film reflecting mirror 15 is a distributed Bragg reflector (DBR) made of a nitride semiconductor material. In other words, the first multilayer film reflecting mirror 15 is a nitride semiconductor multilayer film reflecting mirror.

The n-type semiconductor layer 17 is an n-type GaN layer formed on the first multilayer film reflecting mirror 15. The n-type semiconductor layer 17 is doped with Si as an n-type impurity.

The n-type semiconductor layer 17 includes a prismatic-shaped lower portion 17A and a cylindrical upper portion 17B disposed on the lower portion 17A. In other words, the n-type semiconductor layer 17 includes the cylindrical upper portion 17B that protrudes from a top surface of the prismatic-shaped lower portion 17A. In other words, the n-type semiconductor layer 17 has a mesa-shaped structure that includes the upper portion 17B. The n-type semiconductor layer 17 includes an exposed portion 17E in which the top surface of the lower portion 17A is partially exposed.

An active layer 19 is formed on the upper portion 17B of the n-type semiconductor layer 17. The active layer 19 is an emission structure layer constituted of a plurality of semiconductor layers forming, for example, a multi-quantum well (MQW) structure. Specifically, the active layer 19 is a layer with a quantum well structure that includes a well layer with an InGaN composition and a barrier layer with a GaN composition. When a current is injected into the surface emitting laser 10, light is generated in the active layer 19.

An intermediate layer 21 is an undoped GaN layer formed on the active layer 19. The intermediate layer 21 has a buffer layer function that increases a distance between the active layer 19 and a p-type semiconductor layer 23 formed on the intermediate layer 21, in order to suppress impurities from diffusing from the p-type semiconductor layer 23 formed on the intermediate layer 21 into the active layer 19.

The p-type semiconductor layer 23 is formed on the intermediate layer 21 as described above, and is a layer that includes a plurality of semiconductor layers doped with a p-type impurity. Mg is doped as a p-type impurity.

An n-electrode 25 is a metal electrode provided on the exposed portion 17E of the n-type semiconductor layer 17. The n-electrode 25 is electrically connected to the n-type semiconductor layer 17. For example, the n-electrode 25 is formed in a ring shape surrounding the upper portion 17B of the n-type semiconductor layer 17. A shape of the n-electrode 25 is not limited thereto, and the n-electrode 25 may be an electrode layer formed in a layered shape over the entire surface of the exposed portion 17E.

An insulating layer 27, which is formed on the p-type semiconductor layer 23, is a layer made of an insulator or a material with a lower conductivity than the p-type semiconductor layer 23. The insulating layer 27 is constituted of a substance with a lower refractive index than the material constituting the p-type semiconductor layer 23, such as SiO₂. The insulating layer 27 is formed in a ring shape on the p-type semiconductor layer 23, and has an opening (not illustrated) in a center portion that exposes the p-type semiconductor layer 23.

An translucent electrode 29 is formed on the insulating layer 27. The translucent electrode 29 is also formed on the p-type semiconductor layer 23 through an opening in the insulating layer 27, and is electrically connected to the p-type semiconductor layer 23. The translucent electrode 29 is formed using a metal oxide that is translucent to the light emitted from the active layer 19, for example, ITO or IZO.

A second multilayer film reflecting mirror 31 is a dielectric multilayer film provided on the translucent electrode 29 on an opening in the insulating layer 27. The second multilayer film reflecting mirror 31 is a dielectric multilayer film mirror constituted of two dielectric films with different refractive indices, such as niobium oxide (Nb₂O₅) and silicon oxide (SiO₂), stacked alternately.

A p-electrode 33 is a metal electrode provided on the translucent electrode 29. The p-electrode 33 is electrically connected to the translucent electrode 29. The p-electrode 33 is formed in a ring shape surrounding the second multilayer film reflecting mirror 31.

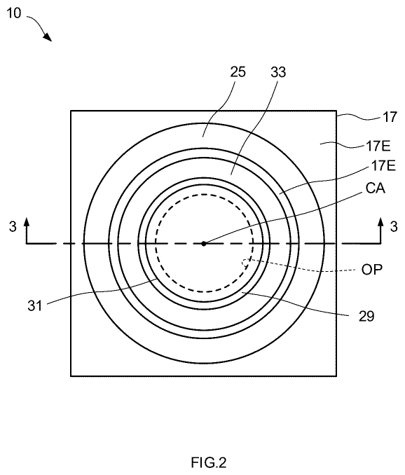

FIG. 2 is atop view of the surface emitting laser 10. As described above, the surface emitting laser 10 includes the n-type semiconductor layer 17 which is formed over the substrate 11 having a rectangular top surface shape and is having a mesa-shaped structure.

The ring-shaped n-electrode 25 is formed on the exposed portion 17E, which is exposed from the mesa-shaped portion of the n-type semiconductor layer 17, so as to surround the mesa-shaped portion.

As described above, the surface emitting laser 10 includes the active layer 19, the intermediate layer 21, the p-type semiconductor layer 23, and the ring-shaped insulating layer 27 (not illustrated in FIG. 2) that are formed in this order on the upper portion 17B, which is the mesa-shaped portion of the n-type semiconductor layer 17, and have a circular top surface shape. The insulating layer 27 has an opening OP.

The translucent electrode 29 is formed on the insulating layer 27 so as to cover the opening OP of the insulating layer 27. The second multilayer film reflecting mirror 31 is provided in a region having a center CA of the translucent electrode 29 on the translucent electrode 29.

The second multilayer film reflecting mirror 31 is formed so as to cover the opening OP in a top view. The second multilayer film reflecting mirror 31 may be formed so as to overlap the opening OP in a top view.

In addition, the ring-shaped p-electrode 33 is provided around a circumference of the translucent electrode 29.

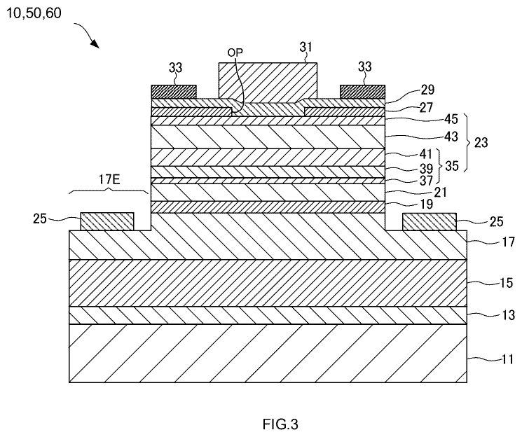

FIG. 3 is a cross-sectional view of the surface emitting laser 10 along the line 3-3 in FIG. 2. As described above, the p-type semiconductor layer 23 is configured including a plurality of semiconductor layers containing a p-type impurity. The following describes a configuration of the p-type semiconductor layer 23.

A p-type AlGaN layer 35 is formed on the intermediate layer 21 and is doped with Mg as a p-type impurity. The p-type AlGaN layer 35 functions as an electron blocking layer.

The p-type AlGaN layer 35 is constituted of three p-type AlGaN layers with mutually different Mg concentration distributions and Al composition distributions. In FIG. 3, the three layers that constitute the p-type AlGaN layer 35 are illustrated as a first layer 37, a second layer 39, and a third layer 41.

In the surface emitting laser 10, it is important to efficiently inject the electron carriers and the hole carriers into the active layer 19 and keep them in the active layer 19, thereby keeping a threshold current density low. If an overflow of the electron carriers occurs, the threshold current density increases, and not only the efficiency of use of the current decreases, but the element also deteriorates due to the effects of heat released by the carriers that do not contribute to luminescence, and the like, which decreases the element life.

By doping Mg into the p-type AlGaN layer 35, which acts as the electron blocking layer, the hole carrier concentration of the p-type AlGaN layer 35 is increased and a Fermi level is lowered. This suppresses the carrier overflow and improves the carrier injection efficiency, which in turn suppresses the increase in the threshold current density of the surface emitting laser 10.

On the other hand, if the Mg concentration in the p-type AlGaN layer 35 is too high, the element life may decrease due to Mg diffusing into the active layer or due to defects caused by Mg spreading to the active layer.

The inventors of the present application have found that in order to increase the carrier injection efficiency while suppressing the above-described decrease in the element life caused by the Mg in the p-type AlGaN layer 35, it is important to precisely control the concentration distribution of the Mg in the p-type AlGaN layer 35 in a layer thickness direction.

In this invention, the Mg concentration is controlled such that the Mg concentration does not become too high in the first layer 37, which is closest to the active layer 19, and the Mg concentration and the Al composition are controlled such that the Mg concentration and Mg concentration distribution are suitable for increasing the carrier injection efficiency in the second layer 39, which is adjacent to the first layer 37, and the third layer 41, which is farthest from the active layer.

As described above, the intermediate layer 21 is provided between the active layer 19 and the p-type semiconductor layer 23. The intermediate layer 21 has a function of increasing a distance between the p-type semiconductor layer 23 and the active layer 19, and suppressing the diffusion of p-type impurity into the active layer 19 and/or the effects of defects caused by p-type impurity. For example, the intermediate layer 21 is formed with a layer thickness of 30 to 145 nm. For example, the surface emitting laser 10 may be configured without the intermediate layer 21.

A p-type nitride semiconductor layer 43 is formed on the p-type AlGaN layer 35 and is a nitride semiconductor layer doped with a p-type impurity. For example, the p-type nitride semiconductor layer 43 is a GaN layer doped with Mg as a p-type impurity.

A p-type contact layer 45 is formed on the p-type nitride semiconductor layer 43 and is a nitride semiconductor layer doped with a p-type impurity at a higher concentration than the p-type nitride semiconductor layer 43. The p-type contact layer 45 is, for example, a GaN layer in which Mg is doped at a higher concentration than the p-type nitride semiconductor layer 43 as a p-type impurity.

Accordingly, the p-type semiconductor layer 23 is constituted of the p-type AlGaN layer 35, the p-type nitride semiconductor layer 43, and the p-type contact layer 45, which are stacked in this order.

The insulating layer 27 is formed on the p-type contact layer 45. As described above, the translucent electrode 29 is formed on the insulating layer 27 to cover the opening OP of the insulating layer 27, and the translucent electrode 29 is in contact with the p-type contact layer 45 through the opening OP.

The p-electrode 33 is electrically in contact with the translucent electrode 29. Therefore, the p-electrode 33 is electrically connected to the p-type semiconductor layer 23 via the translucent electrode 29.

In the surface emitting laser 10, the current is injected into the p-type semiconductor layer 23 from only a portion that is exposed by the opening OP of the insulating layer 27. Therefore, the opening OP serves as a current constriction structure that limits a range of current supply to the active layer 19.

In the surface emitting laser 10, the first multilayer film reflecting mirror 15 and the second multilayer film reflecting mirror 31 are arranged opposed to one another. The first multilayer film reflecting mirror 15 has a slightly lower reflectance than the second multilayer film reflecting mirror 31. Therefore, a part of the light that is emitted from the active layer 19 and resonates between the first multilayer film reflecting mirror 15 and the second multilayer film reflecting mirror 31 passes through the first multilayer film reflecting mirror 15 and the substrate 11, and is extracted to the outside.

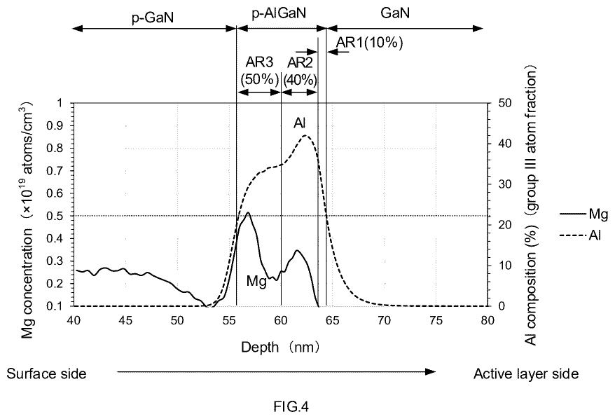

FIG. 4 shows a SIMS analysis result of the p-type AlGaN layer 35 of the surface emitting laser 10 according to Embodiment 1. FIG. 4 shows the Al composition profile and the Mg concentration profile in a depth direction, that is, the layer thickness direction, from the p-type nitride semiconductor layer 43, which is an upper layer of the p-type AlGaN layer 35, toward the intermediate layer 21, which is a lower layer of the p-type AlGaN layer 35 (that is, from the surface side to the active layer side (the substrate 11 side)).

In FIG. 4, the horizontal axis indicates the layer thickness from the surface side toward the active layer side, that is, the depth (nm), the main axis indicates the Mg concentration, and the secondary axis indicates the Al composition. In FIG. 4, the Al composition curve, which shows the change in the Al composition in the depth direction, is indicated as a broken line. In FIG. 4, the Mg concentration curve, which shows the change in the Mg concentration in the depth direction, is indicated as a solid line.

For the Al composition curve illustrated in FIG. 4, a range of a full width at half maximum as the width at 50% of the maximum peak of the Al composition is defined as the p-type AlGaN layer 35. In this embodiment, the p-type AlGaN layer defined on the Al composition curve is divided into three regions in the layer thickness direction. Specifically, the p-type AlGaN layer 35 is divided into a region having a layer thickness of one-tenth (10%) as a first region AR1, a region having a layer thickness of two-fifths (40%) as a second region AR2, and a region having a layer thickness of half (50%) as a third region AR3 in this order from the active layer side toward the surface side in the layer thickness direction, and the Al composition and Mg concentration are described.

Therefore, when focusing on the horizontal axis indicating the layer thickness in the graph shown in FIG. 4, the above-described full width at half maximum corresponds to a total layer thickness of the p-type AlGaN layer 35, and on this horizontal axis, the first region AR1 corresponds to the layer thickness portion of one-tenth of the p-type AlGaN layer 35, the second region AR2 corresponds to the layer thickness portion of two-fifths, and the third region AR3 corresponds to the layer thickness portion of the one-half.

### [Mg Concentration Curve]

First, the Mg concentration and the profile of the Mg concentration in the layer thickness direction indicated by the Mg concentration curve are described.

As illustrated in FIG. 4, the Mg concentration indicated by the Mg concentration curve is less than 1×10¹⁹ atoms/cm³ throughout the entire layer thickness of the p-type AlGaN layer 35. By keeping the Mg concentration less than 1×10¹⁹ atoms/cm³, the diffusion of Mg into the active layer and the spread of defects caused by Mg into the active layer are suppressed. This suppresses the decrease in the element life caused by the high concentration of Mg.

When the peak concentration of Mg in the p-type AlGaN layer 35 reaches 3×10¹⁹ atoms/cm³ or more, the carrier injection efficiency improves due to the presence of a large amount of Mg, but the element life tends to decrease because Mg diffuses easily into the active layer and the defects caused by Mg tend to spread into the active layer.

Therefore, by controlling the Mg concentration in the p-type AlGaN layer 35 to less than 3×10¹⁹ atoms/cm³, and more preferably to less than 1×10¹⁹ atoms/cm³, it is possible to suppress the decrease in the element life caused by such high concentration of Mg.

In this embodiment, in order to suppress the decrease in the element life caused by the above-described high Mg concentration, the Mg concentration is controlled to less than 1×10¹⁹ atoms/cm³ throughout the entire layer thickness of the p-type AlGaN layer 35 in the Mg concentration curve.

In addition, among the regions of the p-type AlGaN layer 35 in the layer thickness direction, the closer the distance to the active layer 19, the easier it is for Mg to diffuse into the active layer 19, and the easier it is for the defects caused by Mg to spread into the active layer. Considering these things, it is preferable that the Mg concentration in the first region AR1, which is closest to the active layer 19, is the lowest, and that the Mg concentration in the third region AR3, which is farthest from the active layer 19, is the highest.

As illustrated in FIG. 4, in this embodiment, when the mean values of the Mg concentrations in the respective regions indicated by the Mg concentration curve are compared between the respective regions, the third region AR3 is the largest, the second region AR2 is the next largest, and the first region AR1 is the smallest (the first region AR1<the second region AR2<the third region AR3). Accordingly, by making the Mg concentration in the first region AR1, which is closest to the active layer 19, the lowest, the diffusion of Mg into the active layer and the spread of the defects caused by Mg into the active layer are suppressed, and the decrease in the element life caused by the high concentrations of Mg is suppressed.

From the perspective of suppressing the decrease in the element life caused by such high concentrations of Mg, it is preferable that the Mg concentration in the first region be less than 2×10¹⁸ atoms/cm³.

Furthermore, in order to ensure the sufficient carrier injection efficiency in the surface emitting laser 10, it is necessary that the Mg concentration in the second region is not too low, and one indicator is that it is at least 3×10¹⁸ atoms/cm³ or more in at least a partial region of the second region AR2. In addition, the profile of the Mg concentration in the second region AR2 is also important, and it has been found that the sufficient carrier injection efficiency can be ensured when the Mg concentration curve has a peak in the second region AR2.

As illustrated in FIG. 4, in this embodiment, the Mg concentration indicated by the Mg concentration curve is 3×10¹⁸ atoms/cm³ or more in at least a partial region of the second region AR2, and the Mg concentration curve has the peak in the second region. By controlling the Mg concentration in this way, the sufficient carrier injection efficiency is ensured, and thereby the increase in the threshold current density is suppressed.

### [Al Composition Curve]

The Al composition curve shown in FIG. 4 has the peak in the second region AR2. In more detail, when comparing the mean values of the Al compositions in the respective regions indicated by the Al composition curve between the respective regions, the second region AR2 is the largest, the third region AR3 is the next largest, and the first region AR1 is the smallest (the first region ART<the third region AR3<the second region AR2).

Increasing the Al composition in the region with the low Mg concentration increases the threshold voltage. Thus, in the first region ART, where the Mg concentration is low, the Al composition is also lowered to suppress the increase in the threshold voltage.

In addition, by making the Al composition in the second region AR2 the highest, the barrier potential can be increased, and the overflow of the electron carriers can be suppressed.

Furthermore, by making only the Al composition of the second region AR2 the highest, rather than increasing the Al composition of the entire p-type AlGaN layer, it is possible to suppress the generation of cracks due to a lattice mismatch between the Al-rich layer and the adjacent GaN layer.

As described above, the surface emitting laser 10 of Embodiment 1 is configured including: a first multilayer film reflecting mirror stacked on a substrate; an n-type nitride semiconductor layer formed on the first multilayer film reflecting mirror; an active layer formed on the n-type nitride semiconductor layer; a p-type AlGaN layer formed on the active layer, containing Mg as a p-type dopant, and having a structure in which three AlGaN layers with different Al compositions are stacked; a p-type nitride semiconductor layer formed on the p-type AlGaN layer; and a second multilayer film reflecting mirror formed on the p-type semiconductor layer and provided in a position opposed to the first multilayer film reflecting mirror.

For the p-type AlGaN layer according to Embodiment 1, assuming that in the Al composition curve indicating the change in the Al composition in the layer thickness direction in the p-type AlGaN layer and the Mg concentration curve indicating the change in the Mg concentration in the layer thickness direction in the p-type AlGaN layer analyzed by a secondary ion mass spectrometry (SIMS) of the p-type AlGaN layer, the range width at 50% of the peak value of the Al composition curve is defined as the p-type AlGaN layer, and the p-type AlGaN layer is divided into the first region having a layer thickness of 1/10 of the p-type AlGaN layer, the second region having has a layer thickness of ⅖ of the p-type AlGaN layer, and the third region having a layer thickness of ½ of the p-type AlGaN layer from the active layer side in this order, the p-type AlGaN layer is defined as follows.

A size relationship among the Al compositions indicated by the Al composition curve in the respective regions is the first region<the third region<the second region. The Mg concentration indicated by the Mg concentration curve is less than 3×10¹⁹ atoms/cm³ throughout the entire layer thickness of the p-type AlGaN layer, and a size relationship among the Mg concentrations in the respective regions is the first region<the second region<the third region. The Mg concentration in at least a partial region of the second region is 3×10¹⁸ atoms/cm³ or more, and the Mg concentration curve has the peak in the second region.

Due to the above-described structure, since the appropriate amount of Mg is contained in the appropriate region of the p-type AlGaN layer in the layer thickness direction, it is possible to suppress the decrease in the element life caused by the excessive Mg while ensuring the sufficient hole carrier concentration in the p-type AlGaN layer.

Accordingly, the surface emitting laser 10 of this embodiment can suppress the decrease in the life of the element while ensuring the high carrier injection efficiency, and can provide the long-life, highly efficient vertical cavity light-emitting element.

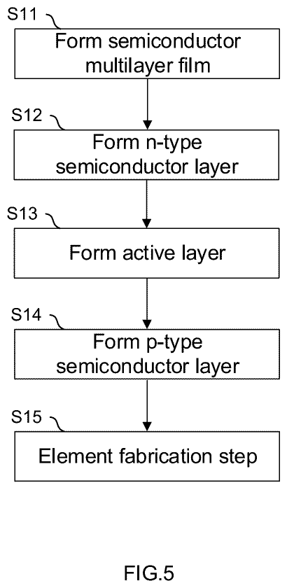

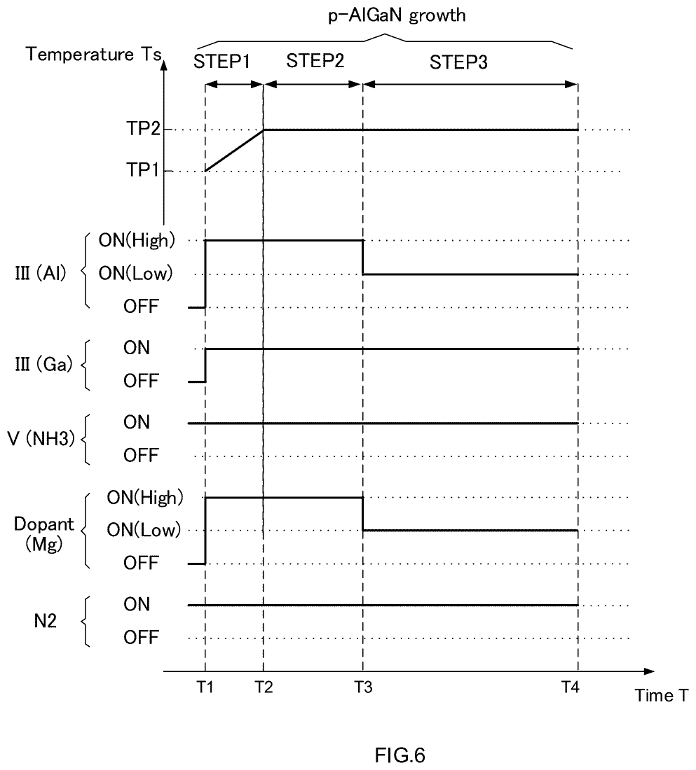

Referring to FIGS. 5 and 6, one example of a manufacturing method of the surface emitting laser 10 is described. FIG. 5 is a flowchart illustrating an overview of a manufacturing process of the surface emitting laser 10. The formation of each semiconductor layer was performed using a metal-organic chemical vapor deposition (MOCVD) method.

First, the underlayer 13 was formed on the substrate 11, and then the first multilayer film reflecting mirror 15 was formed on the underlayer 13 (Step S11).

A C-plane GaN substrate was used for the substrate 11 as a growth substrate. Although not illustrated in the diagram, in a semiconductor layer growth device, the substrate 11 is placed on a susceptor. In addition, a thermocouple is placed under the susceptor, and a temperature of the thermocouple is referred to as a “substrate temperature” in this specification. In addition, a “growth temperature” in this specification refers to the substrate temperature.

In Step S11, the temperature of the substrate 11 was first raised to 1200° C., and a 100 nm of the underlayer 13 made of undoped GaN was grown by supplying trimethylgallium (hereinafter referred to as TMG) and ammonia (NH3) gas in a hydrogen carrier gas (ambient gas). In the case of homoepitaxial growth, it is not necessary to stack the underlayer 13, and it is optional.

Subsequently, the first multilayer film reflecting mirror 15 was then formed. A semiconductor distributed Bragg reflector (DBR) of a stacked body made of InAlN/GaN was grown on the underlayer 13.

First, an InAlN layer was grown on the underlayer 13. The substrate temperature was set to 950° C., and the carrier gas was nitrogen (N2). Trimethylindium (hereinafter referred to as TMI), which is an In material gas, trimethylaluminum (hereinafter referred to as TMA), which is an Al material gas, and ammonia gas were supplied in order to grow the InAlN layer.

Subsequently, a GaN layer was grown on the InAlN layer. The substrate temperature was increased to 1100° C., the carrier gas was changed to hydrogen gas, and trimethylgallium (hereinafter referred to as TMG), which is a Ga material gas, and ammonia gas were supplied to form a GaN layer on the InAlN layer.

After that, the process of growing the InAlN layer and the process of growing the GaN layer described above were repeated a further 40 times, and a total of 41 pairs of the InAlN layers and the GaN layers were stacked. AlInN and GaN were formed in layers on a (0001) plane of a crystal plane of the substrate 11, and the thickness of each layer was made to be ¼ of an optical layer thickness for a desired wavelength.

After that, an n-type semiconductor layer 17 was formed on the first multilayer film reflecting mirror 15 (Step S12). In Step S12, with a substrate temperature of 1200° C. and hydrogen gas as the carrier gas, TMG as the gallium material gas, ammonia gas as the nitrogen source gas, and disilane (Si₂H₆) as a n-type dopant material gas and a silicon-containing gas were supplied to form a 1500 nm of an n-type GaN layer doped with 3×10¹⁸ atoms/cm³ Si (high-temperature n-GaN layer) on the first multilayer film reflecting mirror 15.

After the formation of the n-type semiconductor layer 17, the active layer 19 was stacked on the n-type semiconductor layer 17 (Step S13).

In Step S13, a multi-quantum well layer (hereinafter referred to as “MQW”) was formed on the n-type semiconductor layer 17. The barrier layer and the well layer are made of InₓAl_{y}Ga_{1-x-y}N. In this embodiment, a 3 nm undoped InGaN (y=0) as a well layer and a 4 nm undoped GaN (x=y=0) as a barrier layer were stacked five times to form a MQW constituted of five pairs.

After the active layer 19 was formed, a p-type semiconductor layer 23 was formed on the active layer 19 (Step S14). In Step 14, a GaN layer having a layer thickness of 130 nm was formed as the intermediate layer 21 on the active layer 19, and the p-type semiconductor layer 23 was formed on the intermediate layer 21.

FIG. 6 schematically illustrates a diagram of a growth sequence (p-type AlGaN layer growth step) of the p-type AlGaN layer 35 of the surface emitting laser 10. In FIG. 6, the horizontal axis indicates a time T. In addition, the vertical axis in FIG. 6 indicates a substrate temperature Ts. In FIG. 6, the ON state or the OFF state is indicated for each supplied gas type, which indicates whether or not it is being supplied, along with the change in the substrate temperature Ts over time. In addition, among the types of supplied gas, for the material gas of aluminum (TMA) and the material gas of magnesium (bis-cyclopentadienyl magnesium (hereinafter referred to as “Cp₂Mg”)), the ON state is indicated as ON (High) when supplied in a large supply amount, and as ON (Low) when supplied in a small supply amount.

As illustrated in FIG. 6, the p-type AlGaN layer 35 was grown in three steps. First, in the first growth step (STEP 1 in the figure), while the substrate temperature was increased from TP1 (950° C., a first temperature) to TP2 (1000° C., a second temperature) over a period of 30 seconds (Time T=T1 to T2), with the carrier gas of nitrogen gas and ammonia gas, TMA as the Al material gas at 9.4 sccm (Standard Cubic Centimeter per Minute) (the first supply amount, ON (High) in the figure) and TMG as the Ga material gas at 1.6 sccm were supplied, and further Cp₂Mg as a Mg material gas at 37.2 sccm (the second supply amount, ON (High) in the figure) was supplied in order to grow the first p-type AlGaN layer (the first layer 37 in FIG. 3). The ammonia gas is used as the nitrogen source gas for the p-type AlGaN layer 35. A design value of a layer thickness of the first p-type AlGaN layer is 0.8 nm. A design value of an Al composition of the first p-type AlGaN layer is 25%.

In the second growth step (STEP 2 in the figure), the substrate temperature was maintained at TP2, and the supplies of TMG, nitrogen gas, ammonia gas, TMA, and Cp₂Mg were continued at the same level as in the first growth step, and the second p-type AlGaN layer (the second layer 39 in FIG. 3) was grown (T=T2 to T3). In the second growth step, TMA was maintained and supplied at the first supply amount and Cp₂Mg was maintained and supplied at the second supply amount. A design value of a layer thickness of the second p-type AlGaN layer is 2.2 nm. A design value of an Al composition of the second p-type AlGaN layer is 42%.

In the third growth step (STEP 3 in the figure), the substrate temperature was maintained at TP2, and while maintaining the supply amounts of TMG, nitrogen gas, and ammonia gas, TMA was supplied at 4.9 sccm (a third supply amount, ON (Low) in the figure), which was smaller than the first supply amount, and Cp₂Mg was supplied at 2.5 sccm (a fourth supply amount, ON (Low) in the figure), which was smaller than the second supply amount, in order to grow a third p-type AlGaN layer (the third layer 41 in FIG. 3) (T=T3 to T4). A design value of a layer thickness of the third p-type AlGaN layer is 7 nm. In addition, a design value of an Al composition of the third p-type AlGaN layer is 28%.

Accordingly, the p-type AlGaN layer 35 having a design value of 10 nm was formed. The supply amount of the Mg material gas in the above-described p-type AlGaN layer growth step does not correspond to the above-described SIMS profile. Specifically, as described above, the supply amount of the Mg material gas in the third growth step is significantly lower than in the first and second growth steps, which is equal to or less than one-tenth thereof. In contrast, the Mg concentration curve in the SIMS analysis result indicated in FIG. 4 indicates that the Mg concentration is highest in the third region.

This is thought to be due to a memory effect of Mg, in addition to the fact that the higher the substrate temperature, the higher the decomposition efficiency of Cp₂Mg and the easier it is for Mg to be incorporated into the growth layer. In the MOCVD method, it is known that a phenomenon called the memory effect occurs, in which a solid-phase thermal diffusion of Mg dopant and Mg raw materials remaining in a chamber and the like, unintentionally mix into the film. For example, if the supply amount of Cp₂Mg is too high in the third growth step, the effect of the Mg component that was supplied and remained in the first and second growth steps is added, and the Mg concentration in the p-type AlGaN layer 35 becomes excessive, for example exceeding 3×10¹⁹ atoms/cm³, which leads to a decrease in the element life.

The above-described growth sequence takes into account these characteristics of Mg and adjusts the supply amount such that the desired SIMS profile can be obtained. Specifically, by making the supply amount of Cp₂Mg in the third growth step (the fourth supply amount) equal to or less than one-tenth of the supply amount of Cp₂Mg in the second growth step (the second supply amount), the Mg concentration is maintained not exceeding 3×10¹⁹ atoms/cm³ due to the memory effect. In this embodiment, the nitrogen gas is used as the carrier gas instead of the hydrogen gas in which Mg is easily incorporated into the layers.

In this embodiment, by making the above-described improvements to the growth method, it is possible to form the p-type AlGaN layer 35 that produces the SIMS profile as indicated in FIG. 4. This in turn suppresses the increase in the threshold current density of the surface emitting laser 10 and also suppresses the decrease in the life.

After the p-type AlGaN layer 35 was formed, a p-type GaN layer doped with 5×10¹⁸ atoms/cm³ of Mg was formed as the p-type nitride semiconductor layer 43. After that, a p-type GaN contact layer doped with equal to or more than 5×10²⁰ atoms/cm³ of Mg was formed on the p-type nitride semiconductor layer 43 as the p-type contact layer 45, and the formation of the p-type semiconductor layer 23 was completed.

### [Element Fabrication Step]

After the p-type semiconductor layer was formed, Mg was activated by heat treatment in a rapid thermal annealing (hereinafter referred to as “RTA”) device. After that, a mesa pattern was formed by photoresist, and dry etching was used to form a mesa structure while also forming an exposed portion 17E (see FIG. 1) where the n-type semiconductor layer 17 was partially exposed around this mesa structure. The photoresist was then removed.

A 150 nm of a silicon oxide (SiO₂) was formed as the insulating layer 27 on the mesa structure and the exposed portion 17E by sputtering. A pattern was formed using photoresist, and etching was performed using buffered hydrofluoric acid (hereinafter referred to as “BHF”), and the opening OP was formed in the insulating layer 27 on the mesa structure as an opening for light emission. The photoresist was then removed.

Indium tin oxide (hereinafter referred to as “ITO”) was formed as the translucent electrode 29 by sputtering to a thickness of approximately 17 nm. A pattern was formed using photoresist, and the ITO was etched using a mixed acid, forming the translucent electrode 29 on the insulating layer 27 on the mesa structure and on the p-type contact layer 45 exposed by the opening OP of the insulating layer 27. After that, the photoresist was removed, and heat treatment was performed using RTA to make the ITO transparent and improve its conductivity.

Using electron beam (hereinafter referred to as “EB”) deposition, a p-side metal layer (the p-electrode 33) that does not cover the opening was formed on the translucent electrode 29 to a thickness of approximately 300 nm. A stacked body of platinum (Pt), gold (Au), and titanium (Ti) was used for the p-side metal layer. Next, the photoresist was removed after a lift-off using a chemical.

After forming a pattern with photoresist, the n-electrode 25, which is electrically connected to the exposed portion 17E of the n-type semiconductor layer 17, was formed by EB deposition to a thickness of about 700 nm. A stacked body of Ti, Al, Pt, and Au was used for the n-electrode. The photoresist was removed by a lift-off using a chemical.

Using EB deposition, 10.5 pairs (approx. 1300 nm) of a dielectric multilayer film (the dielectric multilayer film mirror, a dielectric DBR) were formed as the second multilayer film reflecting mirror 31 on the translucent electrode 29. A stacked body of niobium oxide (hereinafter, Nb₂O₅, with a film thickness of approx. 45 nm) and SiO₂ (with a film thickness of approx. 76 nm) was used for the dielectric DBR. Next, a dielectric DBR pattern was formed using photoresist, and unnecessary portions of the dielectric DBR (on the p-electrode and the n-electrode) were etched away using a dry etching device. Finally, the photoresist was removed using a chemical.

A pattern was formed using photoresist, and an additional p-side metal layer (not illustrated) electrically connected to the p-electrode was formed to a thickness of approximately 2200 nm using EB deposition. A stacked body of Ti, Pt, and Au was used for the p-electrode (the p-pad layer). Next, the photoresist was removed by a lift-off using a chemical. The element was fabricated in this way (Step S15).

The above-described steps were used to manufacture the surface emitting laser 10.

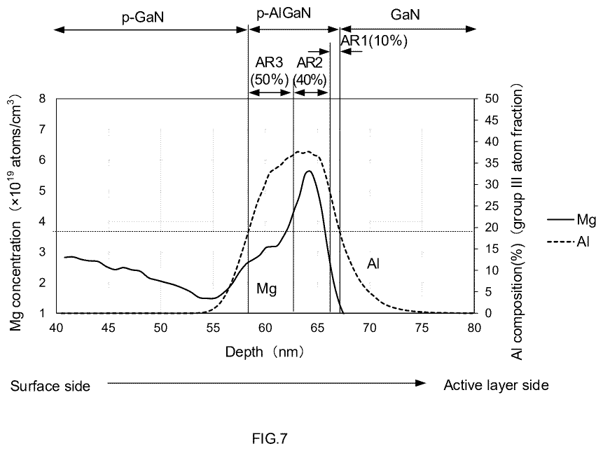

Referring to FIG. 7, a p-type AlGaN layer of a surface emitting laser of Comparative Example 1 is described. The surface emitting laser of Comparative Example 1 is different from that of Embodiment 1 in that it includes, instead of the p-type AlGaN layer 35, a p-type AlGaN layer grown with a constant supply amount of 4.9 sccm of the Al material gas (TMA) and a constant supply amount of 37.2 sccm of the Mg material gas (Cp₂Mg) with a design value of a layer thickness of 10 nm and a design value of an Al composition of 30%. The surface emitting laser of Comparative Example 1 is configured in the same way as that of Embodiment 1 in all other respects. In other words, the p-type AlGaN layer of Comparative Example 1 was grown in a single step, and was grown using a method that differs from the growth method of Embodiment 1, which involves the three steps.

FIG. 7 shows a SIMS analysis result of the p-type AlGaN layer of the surface emitting laser of Comparative Example 1. As with the graph illustrated in FIG. 4, the broken line in FIG. 7 indicates the Al composition curve, which indicates the change in the Al composition in the depth direction, and the solid line indicates the Mg concentration curve, which indicates the change in the Mg concentration in the depth direction. As in the case of Embodiment 1 illustrated in FIG. 4, the width at 50% of the maximum peak of the Al composition is defined as the p-type AlGaN layer, and the p-type AlGaN layer is divided into the first region ART having a layer thickness of 10%, the second region AR2 having a layer thickness of 40%, and the third region AR3 having a layer thickness of 50%, in this order from the active layer side toward the surface side of the p-type AlGaN layer 35.

As illustrated in FIG. 7, the Mg concentration curve has a peak in the second region AR2, and exceeds 3×10¹⁹ atoms/cm³ in most of the second region AR2 and the third region AR3. Accordingly, when the Mg concentration in the second region becomes high concentration exceeding 3×10¹⁹ atoms/cm³, the carrier injection efficiency becomes high, but the diffusion of Mg into the active layer and the spread of defects caused by Mg into the active layer also occur more easily, and this reduces the element life.

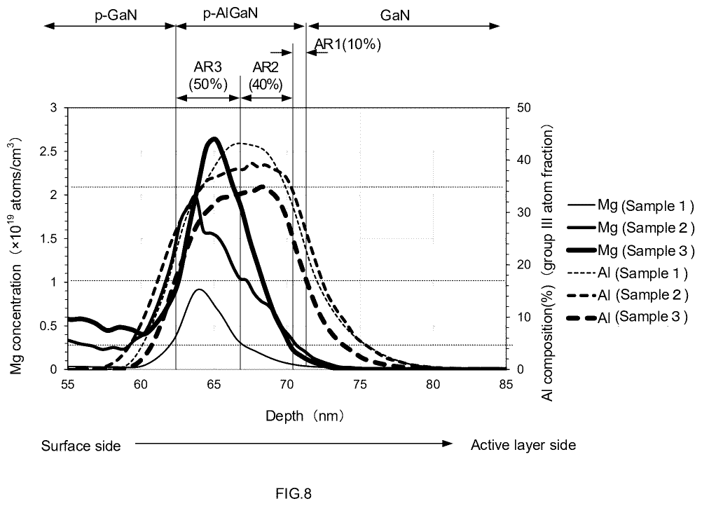

Referring to FIG. 8, a p-type AlGaN layer of a surface emitting laser of Comparative Example 2 is described. The surface emitting laser of Comparative Example 2 is different from those of Embodiment 1 or Comparative Example 1 in that it includes a p-type AlGaN layer that was grown using a different method than the p-type AlGaN layer 35 of Embodiment 1 or the p-type AlGaN layer of Comparative Example 1, and in other respects it is configured in the same way as Embodiment 1.

The p-type AlGaN layer of Comparative Example 2 was grown such that the Mg concentration was less than 3×10¹⁹ atoms/cm³ throughout the entire layer thickness. In Comparative Example 2, respective three samples were made with maximum Mg concentrations of 0.9×10¹⁹ atoms/cm³, 2.0×10¹⁹ atoms/cm³, and 2.6×10¹⁹ atoms/cm³.

The sample with the maximum Mg concentration of 0.9×10¹⁹ atoms/cm³ (hereinafter also referred to as “Sample 1”) was grown by maintaining the supply amount of the Al material gas (TMA) at 6.0 sccm and the supply amount of the Mg material gas (Cp₂Mg) at 37.2 sccm, with a design value of a layer thickness of 10 nm and a design value of an Al composition of 30%.

For the sample with the maximum Mg concentration of 2.0×10¹⁹ atoms/cm³ (hereinafter also referred to as “Sample 2”) was grown by maintaining the supply amount of the Al material gas (TMA) at 6.0 sccm and supplying the Mg material gas (Cp₂Mg) at 37.2 sccm up to 5 nm growth, and then at 2.5 sccm for further 5 nm growth, and the sample was grown with a design value of a layer thickness of 10 nm and a design value of an Al composition of 30%.

For the sample with the maximum Mg concentration of 2.6×10¹⁹ atoms/cm³ (hereinafter also referred to as “Sample 3”) was grown by maintaining the supply amount of the Al material gas (TMA) at 4.9 sccm and supplying amount of the Mg material gas (Cp₂Mg) at 37.2 sccm up to 5 nm growth, and then at 2.5 sccm for further 5 nm growth, and the sample was grown with a design value of a layer thickness of 10 nm and a design value of an Al composition of 30%.

FIG. 8 shows a SIMS analysis result of a p-type AlGaN layer of a surface emitting laser of Comparative Example 2. In FIG. 8, the Al composition curve, which indicates the change in the Al composition in the depth direction, is indicated as the broken line, and the Mg concentration curve, which indicates the change in the Mg concentration in the depth direction, is indicated as the solid line. The Al composition curve and the Mg concentration curve are indicated for the sample of the 2.0×10¹⁹ atoms/cm³ (Sample 2) with thicker lines than for Sample 1, and the sample of the 2.6×10¹⁹ atoms/cm³ (sample 3) with thicker lines than for sample 2.

In FIG. 8, the Mg concentration curve of Sample 3 has the maximum Mg concentration of less than 3×10¹⁹ atoms/cm³, and has a low Mg concentration in the first region (AR1) and a peak in the third region (AR3), which is the farthest from the active layer. Thus, since the peak concentration of Mg is low and the peak is present in a region far from the active layer, it is preferred that the diffusion of Mg into the active layer and the effect of defects caused by Mg on the active layer are unlikely to occur.

On the other hand, the Mg concentration curve of Sample 3 indicates a monotonous decrease toward the active layer in the second region AR2. In this case, it was found that, despite the fact that the hole carrier concentration exceeded 3×10¹⁸ atoms/cm³, which is one of the indicators for obtaining the sufficient hole carrier concentration in almost the entire second region AR2, the hole carrier concentration was insufficient, the overflow of the electron carriers could not be suppressed, the carrier injection efficiency decreased, and the threshold current density increased.

Sample 2 also has a concentration of less than 3×10¹⁹ atoms/cm³, and Sample 1 has an even lower maximum Mg concentration of less than 1×10¹⁹ atoms/cm³. Thus, it is preferred in that it is unlikely that Mg diffuses into the active layer and/or that the defects caused by Mg affects the active layer.

However, in Sample 2 and Sample 1, the Mg concentration in the second region AR2 decreases even further than in Sample 3, resulting in a shortage of the hole carrier concentration and a decrease in the carrier injection efficiency.

As described with reference to FIGS. 7 and 8, in Comparative Example 1, a sample was prepared with a peak concentration of Mg of 3×10¹⁹ atoms/cm³ or more, and in Comparative Example 2, a sample was prepared with a peak concentration of Mg of less than 3×10¹⁹ atoms/cm³, but in both cases, the Mg concentration profile could not be controlled properly.

Specifically, in Comparative Example 1, if the peak concentration of Mg is set to 3×10¹⁹ atoms/cm³ or more, a peak with a high Mg concentration appears in a region close to the active layer 19, and the diffusion of Mg into the active layer and the effect of defects cause by Mg on the active layer become significant. This reduces the element life.

In addition, in Comparative Example 2, if the peak concentration of Mg is set to 3×10¹⁹ atoms/cm³ or less, a position where the peak of the Mg concentration curve appears becomes the third region AR3, and the Mg concentration in the second region monotonically decreases toward the active layer, and the carrier injection efficiency decreases due to the decrease in the hole carriers, leading to an increase in the threshold current density. The increase in the threshold current density also reduces the element life.

In contrast, in Embodiment 1, the Mg concentration indicated by the Mg concentration curve is less than 1×10¹⁹ atoms/cm³ throughout the entire layer thickness of the p-type AlGaN layer 35, and the Mg concentration curve has a peak exceeding 3×10¹⁹ atoms/cm³ in the second region AR2. The p-type AlGaN layer 35, which indicates such a Mg profile, can suppress the decrease in the element life caused by the excessive Mg while providing the sufficient hole carrier concentration in the p-type AlGaN layer. The p-type AlGaN layer 35, which indicates such a Mg profile, can be achieved by growing it using the method that includes the three steps as illustrated in FIG. 6.

In this embodiment, the layer thickness of the first p-type AlGaN layer is preferably 0.4 nm or more and 1 nm or less. If it is less than 0.4 nm, the effect of suppressing the diffusion of Mg into the active layer and the spread of defects caused by Mg into the active layer is poor, and if it exceeds 1 nm, there is a risk of causing an increase in the element voltage.

In this embodiment, it is preferred that a design value of an Al composition of the first p-type AlGaN layer is 25% or less. This is because if the Al composition exceeds 25%, there is a risk that the element voltage is likely to increase.

In this embodiment, a design value of an Al composition of the second p-type AlGaN layer is preferably 33% or more and 50% or less. If the Al composition is less than 33%, it becomes easier for the overflow of the electron carriers to occur, and the threshold current density is more likely to increase. If the Al composition exceeds 50%, the effects of the decrease in crystallinity of the p-type AlGaN layer, the occurrence of cracks, and the increase in the operating voltage become more significant.

In this embodiment, the layer thickness of the second p-type AlGaN layer is preferably 2 nm or more and 6 nm or less. If it is less than 2 nm, it is difficult to achieve the Mg concentration of 3×10¹⁸ atoms/cm³ or more in the second region, and if it exceeds 6 nm, the element voltage may increase significantly.

In this embodiment, a design value of an Al composition of the third p-type AlGaN layer is preferably 20% or more and 30% or less. By setting the Al composition of the third p-type AlGaN layer to this range, it is possible to suppress the occurrence of cracks and increase in the operating voltage while also suppressing the overflow of the electron carriers together with the second p-type AlGaN layer.

In addition, in this embodiment, it is preferred that the layer thickness of the third p-type AlGaN layer is greater than the layer thickness of the second p-type AlGaN layer. By making the layer thickness of the third p-type AlGaN layer thicker than the layer thickness of the second p-type AlGaN layer, the average Al composition of the entire p-type AlGaN layer 35 can be lowered, which suppresses the occurrence of cracks.

### Embodiment 2

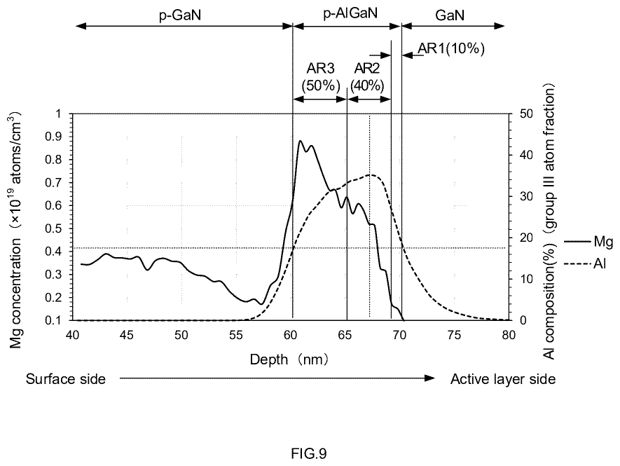

Referring to FIG. 9, the configuration of a surface emitting laser 50 according to Embodiment 2 is described. The surface emitting laser 50 is configured in the same way as the surface emitting laser 10 of Embodiment 1, which is described with reference to FIGS. 1 to 3. However, only the configuration of the p-type AlGaN layer 35 differs from that of the surface emitting laser 10. Specifically, the p-type AlGaN layer 35 of Embodiment 2 has a different profile of the Al composition and the Mg concentration in the layer thickness direction than that of Embodiment 1 obtained by the SIMS analysis.

FIG. 9 shows a SIMS analysis result of the p-type AlGaN layer 35 of the surface emitting laser 50, which was performed in the same way as in Embodiment 1. In FIG. 9, as in Embodiment 1, the full width at half maximum of the Al composition (%) is defined as the p-type AlGaN layer 35, and it is divided into the first region ART to the third region AR3 in this order in the layer thickness direction of the p-type AlGaN layer 35. In FIG. 9, the Al composition curve is indicated as the broken line, and the Mg concentration curve is indicated as the solid line.

As illustrated in FIG. 9, the Mg concentration indicated by the Mg concentration curve is less than 1×10¹⁹ atoms/cm³ throughout the entire layer thickness of the p-type AlGaN layer 35, which is the same as in Embodiment 1. In addition, when comparing the mean values of the Mg concentrations in the respective regions indicated by the Mg concentration curve between the respective regions, the third region AR3 is the largest, the second region AR2 is the next largest, and the first region ART is the smallest (the first region AR1<the second region AR2<the third region AR3), which is also the same as in Embodiment 1. By controlling the Mg concentration throughout the entire layer thickness of the p-type AlGaN layer 35 and the Mg concentrations in the respective regions, the diffusion of Mg into the active layer and the spread of defects caused by Mg into the active layer are suppressed, thereby suppressing the decrease in the element life.

In the Mg concentration curve indicated in FIG. 9, the mean value of the Mg concentrations in the second region is 3×10¹⁹ atoms/cm³ or more. As indicated in FIG. 9, the Mg concentration curve has a peak in the third region, and includes a flatter portion than other portions (approximately flat portion) that extends to a partial region of the second region AR2 and a partial region of the third region AR3, centered around a boundary between the second region AR2 and the third region AR3.

In more detail, in FIG. 9, when the Mg concentration curve in the second region is divided into the first region side and the third region side, with the center of the second region in the layer thickness direction as the dividing line, a slope of a portion of the third region side is gentler than a slope of a portion of the first region side.

In an example graph shown in FIG. 9, an absolute value of the slope of an approximation formula for the portion of the first region side (hereinafter, the slope is expressed in the absolute values) is approximately 2×10¹⁸, and the slope of the approximation formula for the portion of the third region side is approximately 2×10¹⁷. In other words, the Mg concentration curve in the second region can be said to have a smaller mean value of the slope in the portion of the third region side than the mean value of the slope in the portion of the first region side with respect to the center of the second region in the layer thickness direction.

It was found that even when the Mg concentration was controlled to the above-described profile, it was possible to suppress the Mg concentration in the second region from becoming too low and to ensure the sufficient carrier injection efficiency. In the surface emitting laser 50 of Embodiment 2, the mean value of the Mg concentrations in the second region is 3×10¹⁸ atoms/cm³ or more. In the Mg concentration curve in the second region, controlling the mean value of the slope in the portion of the third region side is smaller than the mean value of the slope in the portion of the first region side with respect to the center of the second region in the layer thickness direction allows the sufficient carrier injection efficiency to be ensured, and thereby the increase in threshold current density can be suppressed.

In this embodiment, when comparing the mean values of the Al compositions in the respective regions indicated by the Al composition curve between the respective regions, the second region AR2 is the largest, the third region AR3 is the next largest, and the first region AR1 is the smallest (the first region AR1<the third region AR3<the second region AR2), which is the same as in Embodiment 1.

### Manufacturing Method of Embodiment 2

The p-type AlGaN layer 35 of Embodiment 2 was grown in three steps in the same sequence as illustrated in FIG. 6. In Embodiment 2, the p-type AlGaN layer 35 was grown with the conditions in which the supply amount of TMA as the Al material gas, a design value of a layer thickness, and a design value of an Al composition for Step 1 and Step 2 were different from those of Embodiment 1 while other conditions are the same as in Embodiment 2.

Specifically, Embodiment 2 differs from Embodiment 1 in that the first supply amount of TMA is set to 6.2 sccm, the design layer thickness of the first p-type AlGaN layer is set to 0.6 nm, a design value of an Al composition is set to 23%, the design layer thickness of the second p-type AlGaN layer is set to 2.4 nm, and a design value of an Al composition is set to 33%, which is lower than in Embodiment 1. The supply amounts of the nitrogen gas and the ammonia gas as the atmosphere gas and the supply amount of TMG as the Ga material gas are the same as in Embodiment 1.

Thus, by adjusting the Al composition ratio according to the supply amount of TMA, it is also possible to adjust how Mg is incorporated into the film. When the SIMS analysis is performed on the grown p-type AlGaN layer 35, a profile similar to that indicated in FIG. 9 is obtained. Specifically, a Mg concentration curve is obtained in which the mean value of the Mg concentrations in the second region is 3×10¹⁸ atoms/cm³ or more, and the mean value of the slope in the portion of the third region side is smaller than the mean value of the slope in the portion of the first region side with respect to the center of the second region in the layer thickness direction.

Accordingly, the manufacturing method of the surface emitting laser 50, which includes the growth method of the p-type AlGaN layer 35 of Embodiment 2, allows the formation of the p-type AlGaN layer containing the appropriate amount of Mg in the appropriate region in the layer thickness direction of the p-type AlGaN layer, and it is possible to suppress the decrease in the element life caused by the excessive Mg while ensuring the sufficient hole carrier concentration.

Accordingly, the surface emitting laser 50 of this embodiment can suppress the decrease in the element life while ensuring the high carrier injection efficiency, and can provide the long-life, highly efficient vertical cavity light-emitting element.

### Modification

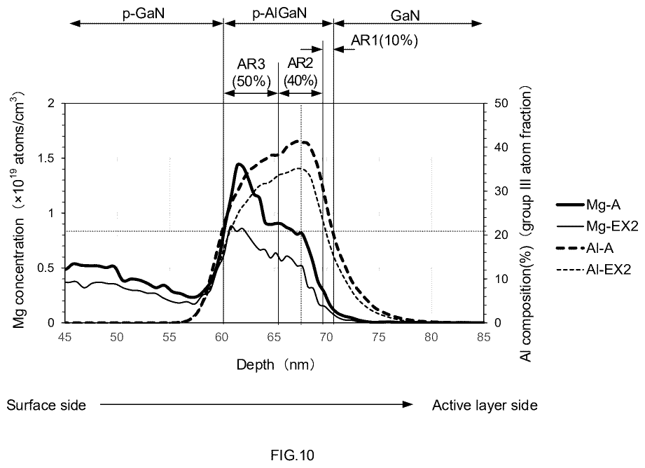

Referring to FIGS. 10 to 14, a configuration of a surface emitting laser 60 according to a modification of Embodiment 2 is described. The surface emitting laser 60 is configured in the same way as the surface emitting laser 50 of Embodiment 2 while only a part of the growth method of the p-type AlGaN layer 35 is different.

FIG. 10 shows an Al composition curve (Al-A) and a Mg concentration curve (Mg-A) obtained by a SIMS analysis of Sample A of the p-type AlGaN layer 35 of the surface emitting laser 60. Similarly to Embodiment 2, a range of a full width at half maximum of the Al composition curve (Al-A) is defined as the p-type AlGaN layer 35, and the p-type AlGaN layer 35 is divided into the first region AR1 to the third region AR3 in the layer thickness direction in this order. In FIG. 10, the Al composition curve of Embodiment 2 is indicated as Al-EX2, and the Mg concentration curve is indicated as Mg-EX2.

As shown in FIG. 10, the Mg concentration curve of the p-type AlGaN layer 35 of the surface emitting laser 60 has the same characteristics as the Mg concentration curve according to Embodiment 2. Specifically, the Mg concentration curve Mg-A according to the modification has the same characteristics as the Mg-EX2 curve of Embodiment 2 in that the mean value of the slope in the portion of the third region side is smaller than the mean value of the slope in the portion of the first region side with respect to the center of the second region in the layer thickness direction.

However, as illustrated in FIG. 10, the Mg concentration curve for the p-type AlGaN layer 35 of the surface emitting laser 60 is shifted toward a high concentration side compared with the Mg concentration curve of Embodiment 2. This shift toward the higher concentration is significant in an area from the second region to the third region, particularly in an area including an approximately flat portion forming a peak shoulder of the third region, which is centered on a boundary between the second region and the third region. The increase in the Mg concentration in this flat portion is preferred in that it increases the hole carrier concentration and improves the carrier injection efficiency.

The above-described shift of the Mg concentration profile toward the high concentration side is due to the addition of a step of supplying the Mg material gas before the start of the growth of the p-type AlGaN layer 35. The following describes the manufacturing method of the p-type AlGaN layer 35 of the surface emitting laser 60.

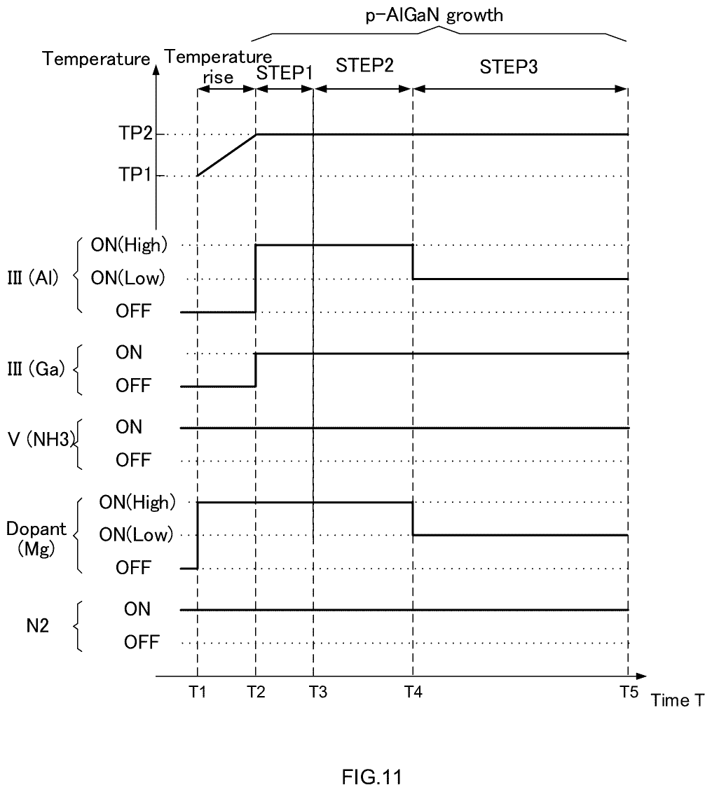

FIG. 11 is a diagram schematically illustrating a p-type AlGaN layer growth step, which is a diagram illustrating a growth sequence for Sample A of the p-type AlGaN layer 35 of the surface emitting laser 60. As illustrated in FIG. 11, in this modification, the p-type AlGaN layer was grown in the three steps after a temperature increase step as a pre-processing step.

During the temperature increase step, while the substrate temperature is increased from TP1 (950° C., a first temperature) to TP2 (1000° C., a second temperature) over a period of 30 seconds (Time T=T1 to T2), the carrier gases were nitrogen gas and ammonia gas, and the Mg material gas (Cp₂Mg) was supplied at 37.2 sccm (a first supply amount, ON (high) in the figure). In the temperature increase step, the Al material gas (TMA) and the Ga material gas (TMG) are not supplied. Therefore, in the temperature increase step, the p-type AlGaN layer does not grow.

After the temperature increase step, in the first growth step (STEP 1 in the figure), the substrate temperature was maintained at TP2 (1000° C., the second substrate temperature), and the carrier gas was continuously supplied as nitrogen gas and ammonia gas as the nitrogen source gas. In the first growth step, TMA as the Al material gas was supplied at 6.2 sccm (the second supply amount, ON (high) in the figure), and TMG as the Ga material gas was supplied at 1.6 sccm (ON in the figure). Furthermore, the Mg material gas (Cp₂Mg) was supplied at 37.2 sccm (the third supply amount, ON (high) in the figure). Under these conditions, the first p-type AlGaN layer (the first layer 37 in FIG. 3) was grown (T2 to T3). A design value of a layer thickness of the first p-type AlGaN layer is 0.6 nm. A design value of an Al composition of the first p-type AlGaN layer is 25%.

After the first growth step, the second growth step (STEP 2 in the figure) and the third growth step (STEP 3 in the figure) progressed in the same way as the second and third growth steps in Embodiment 2.

In the second growth step, the substrate temperature was maintained at TP2, and TMG, nitrogen gas, ammonia gas, TMA, and Cp₂Mg were supplied at the supply amounts maintained from the first growth step, and the second p-type AlGaN layer (the second layer 39 in FIG. 3) was grown (T=T3 to T4). In the second growth step, TMA was supplied at the maintained second supply amount and Cp₂Mg was supplied at the maintained third supply amount. A design value of a layer thickness of the second p-type AlGaN layer is 2.4 nm. A design value of an Al composition of the second p-type AlGaN layer is 33%.

After the second growth step, in the third growth step, the substrate temperature was maintained at TP2, and while maintaining the supply amounts of TMG, nitrogen gas, and ammonia gas, TMA was supplied at 4.9 sccm (a fourth supply amount, ON (Low) in the figure) lower than the second supply amount, and Cp₂Mg was supplied at 2.5 sccm (a fifth supply amount, ON (Low) in the figure) lower than the third supply amount.) in order to grow the third p-type AlGaN layer (the third layer 41 in FIG. 3) (T=T4 to T5). A design value of a layer thickness of the third p-type AlGaN layer is 7 nm. A design value of an Al composition of the third p-type AlGaN layer is 28%.

As described above, the p-type AlGaN layer 35 according to the modification was formed with a design value of 10 nm.

In the above-described description, an example in which the processing time (T1 to T2) (that is, the heating time) in the temperature increase step was set to 30 seconds, and the supply amount of the Mg material gas (the first supply amount) was set to 37.2 sccm is described. In this modification, it was found that it was possible to adjust the Mg concentration of the second region by adjusting the heating time and the supply amount of the Mg material gas.

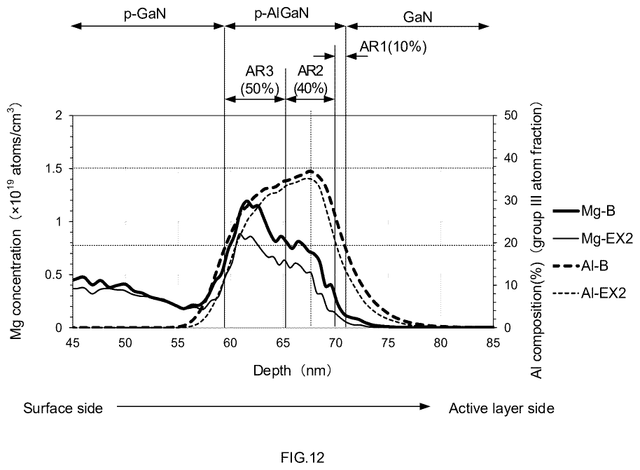

FIG. 12 shows the Al composition curve and the Mg concentration curve for Sample B of the p-type AlGaN layer 35 grown under the same conditions as described in FIG. 11 except for the Mg material gas supply amount (the first supply amount) during the temperature increase step set to 75 sccm and the temperature increase time set to 15 seconds, together with the results of Embodiment 2.

In a region including an approximately flat portion as a shoulder portion of the peak in the third region centered on the boundary between the second region and the third region, the Mg concentration curve shifts toward the high concentration side compared with Embodiment 2. The extent of the increase in the Mg concentration for Sample B compared with Embodiment 2 is about the same as the extent of the increase for Sample A illustrated in FIG. 10.

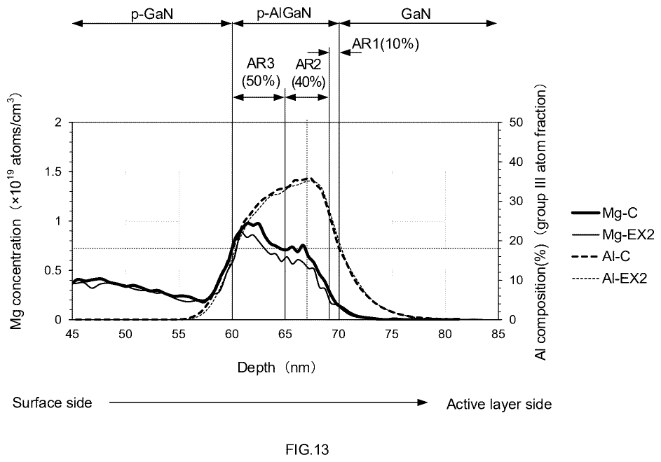

FIG. 13 shows the Al composition curve and the Mg concentration curve for Sample C of the p-type AlGaN layer 35 grown using the same method as described in FIG. 11 except for the Mg material gas supply amount (the first supply amount) of 37.5 sccm and the heating time of 15 seconds in the temperature increase step. The extent of the increase in the Mg concentration is smaller than the extent of the increase in Sample A shown in FIG. 10. However, Sample C has the Mg concentration of less than 1×10¹⁹ atoms/cm³ throughout the entire layer thickness of the p-type AlGaN layer 35. According to the conditions of Sample C, it can be said that the Mg concentration in the second region can be shifted toward the high concentration side within the range of less than 1×10¹⁹ atoms/cm³ throughout the entire layer thickness.

From the above, it was found that the Mg concentration in the flat portion of the Mg concentration profile in the second region, that is, the portion of the third region side with respect to the center of the second region in the layer thickness direction, increases in accordance with the heating time in the temperature increase step, that is, the supply time of the Mg material gas and the supply amount of the Mg material gas. In addition, it was found that the extent of the increase in the Mg concentration in the flat portion was generally correlated with a product of the supply time and the supply amount of the Mg material gas.

As described above, the Mg memory effect is likely to occur when growing the p-type AlGaN layer, and the higher the substrate temperature, the more easily Cp₂Mg decomposes into Mg. In this modification, by supplying the Mg material gas first during the temperature increase step taking into account the effects of the memory effect and the substrate temperature, the Mg concentration profile can be reliably controlled.

As described above, according to the p-type AlGaN layer growth step of this modification, the Mg concentration in the p-type AlGaN layer is less than 3×10¹⁹ atoms/cm³, preferably less than 1×10¹⁹ atoms/cm³, and the mean value of the Mg concentrations in the second region is 3×10¹⁸ atoms/cm³ or more. The Mg concentration curve in the second region can be reliably controlled such that the mean value of the slope in the portion of the third region side is smaller than the mean value of the slope in the portion of the first region side with respect to the center of the second region in the layer thickness direction.

### Embodiment 3

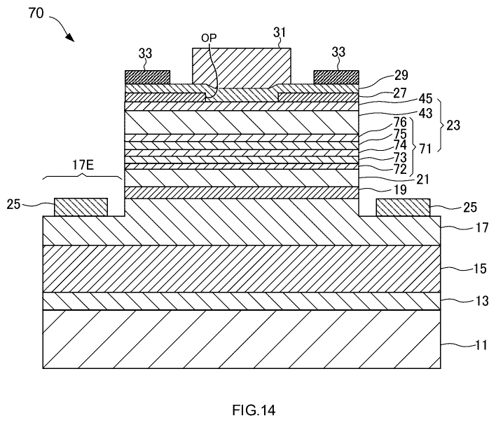

Referring to FIGS. 14 to 16, a surface emitting laser 70 according to Embodiment 3 is described. FIG. 14 is a cross-sectional view illustrating a configuration of the surface emitting laser 70. The surface emitting laser 70 is configured basically the same as the surface emitting laser 10 of Embodiment 1 and the surface emitting laser 50 of Embodiment 2.

The surface emitting laser 70 differs from the surface emitting laser 10 or the surface emitting laser 50 in that it includes a p-type AlGaN layer 71 with a five-layer structure instead of the p-type AlGaN layer 35 with a three-layer structure.

The p-type AlGaN layer 71 is formed on the intermediate layer 21 similarly to the p-type AlGaN layer 35, and is an AlGaN layer doped with Mg as a p-type impurity that functions as the electron blocking layer.

The p-type AlGaN layer 71 is constituted of five layers of p-type AlGaN layers with mutually different Mg concentration distributions and the Al composition distributions. In FIG. 14, the five layers that constitute the p-type AlGaN layer 71 are illustrated as a first layer 72, a second layer 73, a third layer 74, a fourth layer 75, and a fifth layer 76.

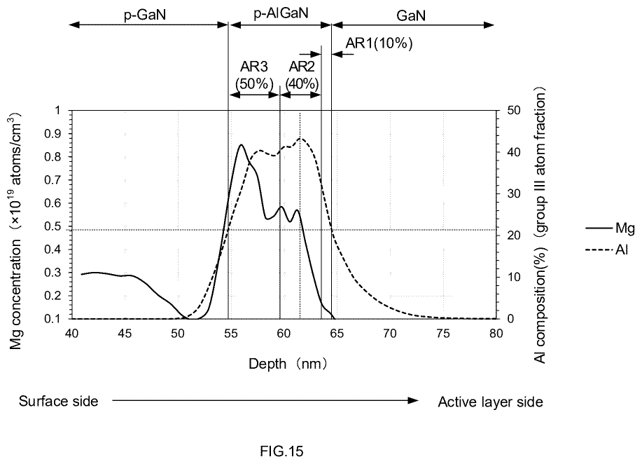

FIG. 15 shows a SIMS analysis result of the p-type AlGaN layer 71 of the surface emitting laser 70, which was performed in the same way as in Embodiment 2. In FIG. 15, as in Embodiment 2, the range of the full width at half maximum of the Al composition (%) is defined as the p-type AlGaN layer 71, and the p-type AlGaN layer 71 is divided into the first region AR1 to the third region AR3 in this order in the layer thickness direction. In FIG. 15, the Al composition curve is indicated as the broken line, and the Mg concentration curve is indicated as the solid line.

As shown in FIG. 15, the Al composition curve and the Mg concentration curve of the p-type AlGaN layer 71 have the same characteristics as in the case of Embodiment 2.

Specifically, the Mg concentration indicated by the Mg concentration curve of the p-type AlGaN layer 71 is less than 1×10¹⁹ atoms/cm³ throughout the entire layer thickness of the p-type AlGaN layer 71, which is the same as the analysis result of Embodiment 2 shown in FIG. 9. In addition, when comparing the mean values of the Mg concentrations in the respective regions indicated by the Mg concentration curve between the respective regions, the third region AR3 is the largest, the second region AR2 is the next largest, and the first region ART is the smallest (the first region ART<the second region AR2<the third region AR3), which is the same as the analysis result of Embodiment 2.

The mean value of the Mg concentrations in the second region of the p-type AlGaN layer 71 is also 3×10¹⁸ atoms/cm³ or more, which is the same as the analysis result of Embodiment 2.

Furthermore, compared with Embodiment 2, in the Mg concentration curve of the p-type AlGaN layer 71, the slope is smaller in the upper layer when the region close to the first region is defined as the lower layer and the region close to the third region is defined as the upper layer, with the center of the second region in the layer thickness direction. In other words, the peak shoulder in the third region is flatter. In addition, the Mg concentration in the upper layer is 5×10¹⁸ atoms/cm³ or more.

As described above, in the Mg concentration curve of the p-type AlGaN layer, if a flat portion appears in a region close to the third region from the center of the layer thickness direction in the second region, the sufficient hole carrier concentration can be obtained, the carrier injection efficiency increases, and the threshold current density can be maintained low. Therefore, also in this embodiment, the high hole carrier concentration is obtained in the p-type AlGaN layer 71. Therefore, it can be said that the surface emitting laser 70 has the high carrier injection efficiency, the low threshold current density, and the long element life.

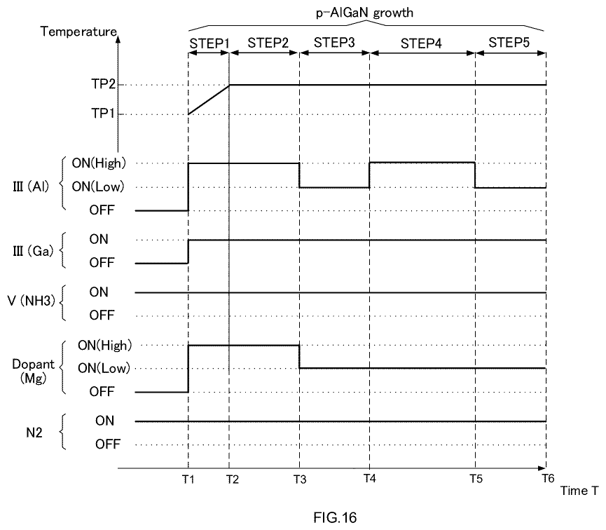

FIG. 16 is a diagram schematically illustrating a growth sequence (the p-type AlGaN layer growth step) of the p-type AlGaN layer 71 of the surface emitting laser 70.

As illustrated in FIG. 16, the p-type AlGaN layer 71 was grown in five steps. The growth sequence illustrated in FIG. 16 progresses in the same way as the growth sequence of Embodiment 1 illustrated in FIG. 6 up to Step 3, but in this embodiment, the design film thickness of Step 3 is smaller than that of Embodiment 1. This embodiment differs from Embodiment 1 in that the steps corresponding to Step 2 and Step 3 of Embodiment 1 are repeated with a smaller design layer thickness in Step 4 and Step 5 after Step 3. Table 1 shows one example of the growth conditions, including the supply amount of each material gas and the design layer thickness, when the p-type AlGaN layer 71 is grown.

TABLE 1

| | | | | | | | Al | Layer |
|---|---|---|---|---|---|---|---|---|
| | Substrate | | | | TMA | Cp₂Mg | composition | thickness |
| | temperature(° C.) | N₂ | NH₃ | TMG | (sccm) | (sccm) | (design) | (design) |
| STEP1 | 950 | ON | ON | 1.6 | 9.4 | 37.2 | 25% | 0.8 nm |
| STEP2 | 1000 | ON | ON | 1.6 | 9.4 | 37.2 | 42% | 2.2 nm |
| STEP3 | 1000 | ON | ON | 1.6 | 4.9 | 2.5 | 28% | 2.0 nm |
| STEP4 | 1000 | ON | ON | 1.6 | 9.4 | 2.5 | 42% | 3.0 nm |
| STEP5 | 1000 | ON | ON | 1.6 | 4.9 | 2.5 | 28% | 2.0 nm |

As illustrated in FIG. 16 and Table 1, in Step 1 to Step 5, the carrier gas was nitrogen gas and ammonia (NH3) gas as the nitrogen source gas, and TMG as the Ga material gas was supplied at a constant supply amount of 1.6 sccm.

The first growth step (STEP 1 in the figure) progressed in the same way as in Embodiment 1. In the first growth step, the substrate temperature was increased from TP1 (950° C., the first temperature) to TP2 (1000° C., the second temperature) in 30 seconds (Time T=T1 to T2), while supplying TMA as the Al material gas at 9.4 sccm (the first supply amount, ON (high) in the figure)) and the Mg material gas (Cp₂Mg) at 37.2 sccm (the second supply amount, ON (high) in the figure) in order to grow the first p-type AlGaN layer (the first layer 72 in FIG. 14) with a design layer thickness of 0.8 nm and a design value of an Al composition of 25%.

In the second growth step (STEP 2 in the figure), the substrate temperature was maintained at TP2 (1,000° C.), and the supply amount of TMA and the supply amount of Cp₂Mg were not changed, the second p-type AlGaN layer (the second layer 73 in FIG. 14) was grown with a design layer thickness of 2.2 nm and a design value of an Al composition of 42% (T2 to T3).

In the third growth step (STEP 3 in the figure), the supply amount of TMA was set to 4.9 sccm (the third supply amount, ON (Low) in the figure), and the supply amount of Cp₂Mg was set to 2.5 sccm (the fourth supply amount, ON (Low) in the figure), which is equal to or less than one-tenth of the second supply amount, the third p-type AlGaN layer (the third layer 74 in FIG. 14) was grown with a design layer thickness of 2.0 nm and a design value of an Al composition of 28% (T3 to T4).

In the fourth growth step (STEP 4 in the figure), the supply amount of TMA was again set to 9.4 sccm (the first supply amount, ON (high) in the figure), and the supply amount of Cp₂Mg was maintained at 2.5 sccm (the fourth supply amount, ON (Low) in the figure), the fourth p-type AlGaN layer (the fourth layer 75 in FIG. 14) was grown with a design layer thickness of 3.0 nm and a design value of an Al composition of 42% (T4 to T5).

In the fifth growth step (STEP 5 in the figure), the supply amount of TMA was reduced to 4.9 sccm (the third supply amount, ON (Low) in the figure), and the supply amount of Cp₂Mg was maintained at 2.5 sccm (the fourth supply amount, ON (Low) in the figure), and a fifth p-type AlGaN layer (the fifth layer 76 in FIG. 14) was grown with a design layer thickness of 2.0 nm and a design value of an Al composition of 28% (T5 to T6).

In this way, the p-type AlGaN layer 71 with a design value of 10 nm was formed. From Step 3 onward, more Mg is incorporated into the layer than expected due to the memory effect of Mg. As described above, by reducing the supply amount of CP2Mg to equal to or less than one-tenth of the first supply amount up to Step 2 from Step 3 onward, the Mg concentration can be maintained less than 3×10¹⁹ atoms/cm³ throughout the entire p-type AlGaN layer.

In Embodiment 3, a layer thickness of the first p-type AlGaN layer is preferably 0.4 nm or more and 1 nm or less. If it is less than 0.4 nm, the effect of suppressing the diffusion of Mg into the active layer and the spread of defects caused by Mg into the active layer is poor, and if it exceeds 1 nm, there is a risk of causing the increase in the element voltage.

In this embodiment, it is preferable that a design value of an Al composition of the first p-type AlGaN layer is 25% or less. This is because if the Al composition exceeds 25%, there is a risk that the element voltage increases.

In this embodiment, design values of Al compositions of the second p-type AlGaN layer and the fourth p-type AlGaN layer are preferably 33% or more and 50% or less. If the Al composition is less than 33%, it becomes easier for the overflow of the electron carriers to occur, and the threshold current density is more likely to increase. If the Al composition exceeds 50%, the effects of the decrease in the crystallinity of the p-type AlGaN layer, the occurrence of cracks, and the increase in the operating voltage become more significant.

In this embodiment, the layer thickness of the second p-type AlGaN layer is preferably 2 nm or more and 3 nm or less. If it is less than 2 nm, it is difficult to make the Mg concentration in the second region 3×10¹⁸ atoms/cm³ or more, and if it exceeds 3 nm, there is a risk of the increase in the element voltage due to the interaction with the fourth p-type AlGaN layer. Similarly, it is preferable that the layer thickness of the fourth p-type AlGaN layer is preferably 2 nm or more and 3 nm or less.

In this embodiment, design values of Al compositions of the third p-type AlGaN layer and the fifth p-type AlGaN layer are preferably 20% or more and 30% or less. By setting the Al compositions of the third p-type AlGaN layer and the fifth p-type AlGaN layer to this range, it is possible to suppress the occurrence of cracks and the increase in the operating voltage while suppressing the overflow of the electron carriers by combination with the second p-type AlGaN layer and the fourth p-type AlGaN layer.

As described above, according to the p-type AlGaN layer growth step of this embodiment, by growing the p-type AlGaN layer in the five steps as described above, the Mg concentration in the p-type AlGaN layer is less than 3×10¹⁹ atoms/cm³, preferably less than 1×10¹9 atoms/cm³, and the mean value of the Mg concentrations in the second region is 3×10¹⁸ atoms/cm³ or more. The Mg concentration curve in the second region can be reliably controlled such that the mean value of the slope in the portion of the third region side is smaller than the mean value of the slope in the portion of the first region side with respect to the center of the second region in the layer thickness direction.

In the above-described embodiment, the case where the layer thickness of the p-type AlGaN layer is 10 nm is described, but this is not limited thereto. The layer thickness of the p-type AlGaN layer is preferably 8 nm or more and 15 nm or less. If the layer thickness is less than 8 nm, the overflow of the electron carriers becomes likely to occur, and the threshold current density becomes likely to increase. If the layer thickness exceeds 15 nm, there is a risk of the occurrence of cracks and the increase in the operating voltage.

In the above-described embodiment, the difference between the Al composition in the second region and the Al composition in the third region indicated by the Al composition curve is preferably 3% or more and 18% or less. For example, if the difference between the maximum Al composition in the second region and the maximum Al composition in the third region (hereinafter simply referred to as “difference in Al composition”) is 3% or more, a flat portion appears in the second region of the Mg concentration curve as in Example 2 and Example 3, and when the difference in Al composition exceeds 8%, a peak appears in the second region of the Mg concentration curve as in Embodiment 1. However, if the difference in Al composition is 18% or more, the crystallinity of the p-type AlGaN layer begins to deteriorate, which is not desirable.

In the above-described embodiment, a nitride semiconductor multilayer film is used as a lower reflecting mirror. Since the thermal conductivity of the nitride semiconductor multilayer film containing AlInN is low, the resonator length is long. Thus, the threshold current density tends to be particularly high in the surface emitting laser that use the nitride semiconductor multilayer films as the reflecting mirror, and this in turn tends to cause the carrier overflow. Therefore, it is effective to apply the present invention to the vertical cavity light-emitting element that uses the nitride semiconductor containing AlInN as the reflector.

The configurations in the above-described embodiments and the manufacturing methods are only examples, and can be changed as appropriate according to the application, and the like.

### DESCRIPTION OF REFERENCE SIGNS

10, 50, 60, 70 Surface emitting laser
11 Substrate
15 First multilayer film reflecting mirror
17 n-type semiconductor layer
19 Active layer
21 Intermediate layer
23 p-type semiconductor layer
25 n-electrode
27 Insulating layer
29 Translucent electrode
31 Second multilayer film
33 p-electrode

1. A vertical cavity light-emitting element comprising:
a substrate;
a first multilayer film reflecting mirror as a semiconductor multilayer film in which two semiconductor layers with mutually different refractive indices are stacked alternately a plurality of times on the substrate;
an n-type nitride semiconductor layer formed on the first multilayer film reflecting mirror and made of a nitride semiconductor containing an n-type dopant;
an active layer formed on the n-type nitride semiconductor layer;
a p-type AlGaN layer formed on the active layer and containing Mg as a p-type dopant, the p-type AlGaN layer having a configuration in which three or more AlGaN layers with different Al compositions are stacked;
a p-type nitride semiconductor layer formed on the p-type AlGaN layer, the p-type nitride semiconductor layer being a semiconductor layer made of a nitride semiconductor containing a p-type dopant; and
a second multilayer film reflecting mirror formed on the p-type nitride semiconductor layer and provided in a position opposed to the first multilayer film reflecting mirror, wherein
in an Al composition curve indicating a change in Al composition in a layer thickness direction in the p-type AlGaN layer and a Mg concentration curve indicating a change in Mg concentration in the layer thickness direction in the p-type AlGaN layer analyzed by a secondary ion mass spectrometry (SIMS) of the p-type AlGaN layer,
when a width range at 50% of the peak value of the Al composition curve is defined as the p-type AlGaN layer, and the p-type AlGaN layer is divided into a first region having a layer thickness of 1/10 of the p-type AlGaN layer, a second region having a layer thickness of ⅖ of the p-type AlGaN layer, and a third region having a layer thickness of ½ of the p-type AlGaN layer in the layer thickness direction from the active layer side in this order,
a size relationship among the Al compositions indicated by the Al composition curve in the respective regions is the first region<the third region<the second region,
a Mg concentration indicated by the Mg concentration curve is less than 3×10¹⁹ atoms/cm³ throughout an entire layer thickness of the p-type AlGaN layer, and a size relationship among the Mg concentrations in the respective regions is the first region<the second region<the third region,
the Mg concentration in at least a partial region of the second region is 3×10¹⁸ atoms/cm³ or more, and
the Mg concentration curve has a peak in the second region.

2. A vertical cavity light-emitting element comprising:
a substrate;
a first multilayer film reflecting mirror as a semiconductor multilayer film in which two semiconductor layers with mutually different refractive indices are stacked alternately a plurality of times on the substrate;
an n-type nitride semiconductor layer formed on the first multilayer film reflecting mirror and made of a nitride semiconductor containing an n-type dopant;
an active layer formed on the n-type nitride semiconductor layer;
a p-type AlGaN layer formed on the active layer and containing Mg as a p-type dopant, the p-type AlGaN layer having a configuration in which three or more AlGaN layers with different Al compositions are stacked;
a p-type nitride semiconductor layer formed on the p-type AlGaN layer, the p-type nitride semiconductor layer being a semiconductor layer made of a nitride semiconductor containing a p-type dopant; and
a second multilayer film reflecting mirror formed on the p-type nitride semiconductor layer and provided in a position opposed to the first multilayer film reflecting mirror, wherein
in an Al composition curve indicating a change in Al composition in a layer thickness direction in the p-type AlGaN layer and a Mg concentration curve indicating a change in Mg concentration in the layer thickness direction in the p-type AlGaN layer analyzed by a secondary ion mass spectrometry (SIMS) of the p-type AlGaN layer,
when a width range at 50% of the peak value of the Al composition curve is defined as the p-type AlGaN layer, and the p-type AlGaN layer is divided into a first region having a layer thickness of 1/10 of the p-type AlGaN layer, a second region having a layer thickness of ⅖ of the p-type AlGaN layer, and a third region having a layer thickness of ½ of the p-type AlGaN layer in the layer thickness direction from the active layer side in this order,
a size relationship among the Al compositions indicated by the Al composition curve in the respective regions is the first region<the third region<the second region,
a Mg concentration indicated by the Mg concentration curve is less than 3×10¹⁹ atoms/cm³ throughout an entire layer thickness of the p-type AlGaN layer, and a size relationship among the Mg concentrations in the respective regions is the first region<the second region<the third region,
a mean value of the Mg concentrations in the second region is 3×10¹⁸ atoms/cm³ or more, and
the Mg concentration curve in the second region is configured such that a mean value of absolute values of a slope in a portion of the third region side is smaller than a mean value of absolute values of a slope in a portion of the first region side with respect to a center of the second region in the layer thickness direction, in the second region.

3. The vertical cavity light-emitting element according to claim 1, wherein the Mg concentration in the p-type AlGaN layer indicated by the Mg concentration curve is less than 1×10¹⁹ atoms/cm³ throughout the entire layer thickness.

4. The vertical cavity light-emitting element according to claim 1, wherein the Mg concentration in the first region indicated by the Mg concentration curve is less than 2×10¹⁸ atoms/cm³.

5. The vertical cavity light-emitting element according to claim 1, wherein a difference between the Al composition in the second region and the Al composition in the third region indicated by the Al composition curve is 3% or more and 18% or less.

6. The vertical cavity light-emitting element according to claim 1, wherein the layer thickness of the p-type AlGaN layer is 8 nm or more and 15 nm or less.

7. A manufacturing method of a vertical cavity light-emitting element by a metal-organic chemical vapor deposition (MOCVD), comprising:
a step of forming a first multilayer film reflecting mirror by alternately growing two semiconductor layers with mutually different refractive indices on a substrate;
an n-type nitride semiconductor layer growth step of growing an n-type nitride semiconductor layer on the first multilayer film reflecting mirror while supplying a material gas of n-type dopant;
a step of forming an active layer on the n-type nitride semiconductor layer;
a p-type AlGaN layer growth step of growing a p-type AlGaN layer that is an AlGaN layer having a p-type conductivity type on the active layer while supplying a material gas of Mg as a p-type dopant;
a p-type nitride semiconductor layer growth step of growing a p-type nitride semiconductor layer on the p-type AlGaN layer; and
a step of forming a second multilayer film reflecting mirror opposed to the first multilayer film reflecting mirror on the p-type nitride semiconductor layer, wherein
the p-type AlGaN layer growth step includes:
a first growth step of growing a first p-type AlGaN layer by supplying a nitrogen source gas and a Ga material gas at a predetermined supply amount, supplying an Al material gas at a first supply amount, and supplying the Mg material gas at a second supply amount while increasing a growth temperature from a first temperature to a second temperature;
a second growth step of growing a second p-type AlGaN layer while maintaining the supply amounts of the nitrogen source gas, the Ga material gas, the Al material gas, and the Mg material gas used in the first growth step after the first growth step; and
a third growth step of growing a third p-type AlGaN layer while supplying the Al material gas at a third supply amount lower than the first supply amount and supplying the Mg material gas at a fourth supply amount lower than the second supply amount after the second growth step.

8. The manufacturing method according to claim 7, further comprising executing the second growth step and the third growth step after executing the third growth step.

9. The manufacturing method according to claim 8, wherein the fourth supply amount is equal to or less than one-tenth of the second supply amount.

10. A manufacturing method of a vertical cavity light-emitting element by a metal-organic chemical vapor deposition (MOCVD), comprising:
a step of forming a first multilayer film reflecting mirror by alternately growing two semiconductor layers with mutually different refractive indices on a substrate;
an n-type nitride semiconductor layer growth step of growing an n-type nitride semiconductor layer on the first multilayer film reflecting mirror while supplying a material gas of n-type dopant;
a step of forming an active layer on the n-type nitride semiconductor layer;
a p-type AlGaN layer growth step of growing a p-type AlGaN layer that is an AlGaN layer having a p-type conductivity type on the active layer while supplying a material gas of Mg as a p-type dopant;
a p-type nitride semiconductor layer growth step of growing a p-type nitride semiconductor layer on the p-type AlGaN layer; and
a step of forming a second multilayer film reflecting mirror opposed to the first multilayer film reflecting mirror on the p-type nitride semiconductor layer, wherein the p-type AlGaN layer growth step includes:
a pre-processing step of supplying a nitrogen source gas at a predetermined supply amount, and supplying the Mg material gas at the first supply amount while increasing a growth temperature from a first temperature to a second temperature;
a first growth step of growing a first p-type AlGaN layer by supplying a Ga material gas at a predetermined supply amount, supplying an Al material gas at a second supply amount, and supplying the Mg material gas at a third supply amount while continuing the supply of the nitrogen source gas after the pre-processing step;
a second growth step of growing a second p-type AlGaN layer while maintaining the supply amounts of the nitrogen source gas, the Ga material gas, the Al material gas, and the Mg material gas used in the first growth step after the first growth step; and
a third growth step of growing a third p-type AlGaN layer while supplying the Al material gas at a fourth supply amount lower than the second supply amount and supplying the Mg material gas at a fifth supply amount lower than the third supply amount after the second growth step.

11. The manufacturing method according to claim 8, wherein in the p-type AlGaN layer growth step, the atmosphere gas is nitrogen gas.

12. The manufacturing method according to claim 10, wherein the third supply amount is equal to or less than the first supply amount.

13. The manufacturing method according to claim 10, wherein the fifth supply amount is equal to or less than one-tenth of the third supply amount.
